(19) United States
(12) Patent Application Publication
(10) Pub. No.: US 2026/0344794 A1
(43) Pub. Date: Nov. 5, 2026

(54) CONTROL BOARD ASSEMBLY FOR AN AEROSOL-GENERATING SYSTEM AND A METHOD OF ASSEMBLING AN AEROSOL-GENERATING DEVICE

(71) Applicant: Philip Morris Products S.A., Neuchatel (CH)

(72) Inventors: Sze Chiek AW, Singapore (SG); Teck Yan CHAN, Singapore (SG); Chunzun CHEN, Xiamen (CN); Xiaojie CHEN, Xiamen (CN); Zhiwei CHEN, Xiamen (CN); Yeong Taur EOW, Singapore (SG); Jean-Luc FRINGELI, Singapore (SG); Jiafeng LI, Xiamen (CN); Seng Eng LIM, Singapore (SG); Chuah Fatt NG, Singapore (SG); Su Min SOH, Singapore (SG); Kim Poh WU, Singapore (SG); Kongfu XING, Xiamen (CN); Tenghuo ZENG, Xiamen (CN)

(73) Assignee: Philip Morris Products S.A., Neuchatel (CH)

(21) Appl. No.: 19/138,972

(22) PCT Filed: Dec. 28, 2022
(86) PCT No.: PCT/CN2022/142595

§ 371 Date: Jun. 13, 2025

(51) Int. Cl. A24F 40/60; A24F 40/20; A24F 40/465; A24F 40/51; A24F 40/70; H05K 1/14; H05K 1/181

(52) U.S. Cl. CPC A24F 40/60; A24F 40/20; A24F 40/465; A24F 40/51; A24F 40/70; H05K 1/148; H05K 1/181; H05K 2201/10106

(57) ABSTRACT

A control board assembly for an aerosol-generating system, including: first and second elongate control boards; a lighting assembly including light emitting elements on one or both of the boards; control electronics distributed over the boards to control operation of the lighting assembly; a hinge element coupling the boards; the control board assembly having unfolded and folded states, in the folded state one of the boards is folded about the hinge element to overlie the other board, the boards being arranged such that in the folded state opposing inward-facing surfaces of the boards are spatially separated; and a separator disposed, in the folded state, between the opposing inward-facing surfaces, a major portion of the separator being planar, the separator including a pair of laterally opposed longitudinally extending edges bent perpendicular to the major portion, feet being defined on each of the edges and located against surface portions of the second board.

The present disclosure relates to a control board assembly for an aerosol-generating system. The present disclosure also relates to an aerosol-generating device including such a control board assembly. The present disclosure also relates to a method of assembling an aerosol-generating device.

Electrically powered aerosol-generating systems are known for use in generating an inhalable aerosol for a user. Such aerosol-generating systems incorporate control electronics for controlling one or more functions of the system, with the control electronics contained within a housing of the system. The one or more control functions can include controlling operation of a lighting element of the system. Where the system includes an electrically powered heating arrangement, the one or more control functions may also include controlling operation of the heating arrangement. Where the components of an aerosol-generating system, such as an aerosol-generating device, are intended to be handheld by a user, the housing will be subject to associated size constraints. These size constraints limit the available volume within the housing for containing the control electronics.

It is desirable to provide a control assembly for an aerosol-generating system in which the control assembly is adapted to address the problems outlined above.

In accordance with a first embodiment of the present disclosure, there is provided a control board assembly for an aerosol-generating system. The assembly may comprise a first elongate control board, a second elongate control board, a lighting assembly comprising one or more light emitting elements, and control electronics distributed over one or both of the first control board and the second control board. The one or more light emitting elements may be arranged on one or both of the first control board and the second control board. At least a portion of the control electronics may be configured to control operation of the lighting assembly. The control board assembly may further comprise a hinge element coupling the first control board to the second control board. The control board assembly may have an unfolded state and a folded state. In the folded state one of the first and second control boards is folded about the hinge element to overlie the other of the first and second control boards. The provision of the hinge element allows the first and second control boards to be arranged to overlie each other in the folded state, whilst still being mechanically coupled to each other. In this manner, the hinge element facilitates a space-efficient design for the control board assembly. Such a space-efficient design may allow for ease of insertion of the control board assembly into the housing of an aerosol-generating device of an aerosol-generating system. The control electronics distributed over one or both of the control boards may include a section for control of the lighting assembly. However, the control electronics may also include sections for control of other functions of the aerosol-generating system. For example, where the control board assembly is intended as part of an aerosol-generating device having an electric heating arrangement, the control electronics may include a section for controlling the distribution of power from a power source to the heating arrangement. Where the aerosol-generating device includes a touch sensor, the control board assembly may be coupled to the touch sensor and include a section for controlling operation of the touch sensor.

Preferably, the lighting assembly may be arranged on an outward-facing surface of the first control board, the outward-facing surface associated with the folded state of the control board assembly.

The first control board and the second control board may be arranged such that in the folded state opposing inward-facing surfaces of the first control board and the second control board are spatially separated from each other. The spatial separation may reduce the likelihood of contact between electrical circuitry and/or components mounted on the opposing inward-facing surfaces of the control boards and thereby reduce the likelihood of damage to the circuitry and/or components.

Advantageously, the control board assembly may further comprise a separator element. Such a separator element provides greater reassurance that contact between the opposing inward-facing surfaces of the control boards is avoided. Preferably, in the folded state the separator element is disposed between the opposing inward-facing surfaces of the first control board and the second control board. The separator element may be formed of sheet metal; however it will be understood that the separator element may be formed from any material having sufficient stiffness to maintain separation of the opposing inward-facing surfaces of the first and second control boards from each other. The separator element may contact respective surface portions of the first control board and the second control board, the surface portions electrically insulated from the control electronics. The separator element may be formed from an electrically insulative material, with the electrically insulative material reducing the likelihood of a short circuit between the opposing first and second control boards in the folded state.

Preferably, the first control board may be formed from a first material composition and the second control board formed from a second material composition. The first material composition may have a lower stiffness than the second material composition. So, the first material composition can be said to be more flexible than the second material composition. Conversely, the second material composition can be said to be more stiff or rigid than the first material composition. The first material composition may comprise any material having a lower stiffness relative to the second material composition. By way of example, the first material composition may comprise one or more polymers, metals, or be a composite of two or more different materials. The second material composition may include conventional circuit board materials as found in printed circuit board design, such as a ceramic material. Alternatively, other materials may be used for the first and second material compositions.

The control board assembly may further comprise a stiffening member, the stiffening member having a stiffness greater than the first material composition. The first control board may be overlaid on a support surface of the stiffening member. In this manner, the stiffening member is able to provide increased rigidity to that part of the first control board which is overlaid on the support surface. Preferably, the stiffening member is arranged to avoid overlying the hinge element, thereby reducing the likelihood of impeding transition of the control board assembly between the unfolded and folded states. In the folded state the stiffening member may be disposed between opposing inward-facing surfaces of the first control board and the second control board. The support surface of the stiffening member may be a planar surface. Where the lighting assembly is to be arranged on an outward-facing surface of the first control board, the provision of a planar support surface for the stiffening member may help to ensure that the first control board (being made from the flexible first material composition) adopts a corresponding planar profile. In turn, this provides structural stability to the outward-facing surface of the first control board when arranging the lighting assembly thereon.

Preferably, the hinge element may be formed of a material composition having a lower stiffness than a material composition of the second control board.

The hinge element may be formed of a resilient and/or bendable material.

By way of example, the hinge element may comprise one or more polymers, metals, or be a composite of two or more different materials.

The hinge element may be configured to provide an electrically conductive pathway between the first control board and the second control board. Conveniently, the electrical conductive pathway may comprise one or more electrically conductive tracks overlaid on or embedded in the hinge element. In this manner, circuitry arranged on the first control board may be electrically coupled to circuitry arranged on the second control board.

The hinge element may be an extended integral portion of the first control board. The extended integral portion may be detachably coupled to the second control board. The detachable coupling between the extended integral portion and the second control board may comprise a push-fit connection interface. The extended integral portion may be coupled to the second control board by an adhesive interface. The adhesive interface may be peelable to allow detachment of the hinge element from the second control board.

Alternatively, the hinge element may be structurally distinct from the first control board and the second control board, with a first end of the hinge element coupled to the first control board and a second end of the hinge element coupled to the second control board. The coupling between the hinge element and one or both of the first control board and the second control board may be a detachable coupling. The detachable coupling may comprise a push-fit connection interface. The hinge element may be coupled to one or both of the first and second control boards by an adhesive interface. The adhesive interface may be peelable to allow detachment of the hinge element from the first and/or second control boards.

In one example, the hinge element may extend between longitudinally-extending edges of the first control board and the second control board. The hinge element may be configured such that transition from the unfolded state to the folded state comprises one of the first and second control boards being folded about an axis extending generally parallel to a longitudinal axis of the other of the first and second control boards.

In another example, the hinge element may extend between laterally-extending edges of the first control board and the second control board. The hinge element may be configured such that transition from the unfolded state to the folded state comprises one of the first and second control boards being folded about an axis extending generally perpendicular to a longitudinal axis of the other of the first and second control boards.

The hinge element may extend between an edge of the first control board and an edge of the second control board. The hinge element may extend between the width edge or the length edge of the first control board and the wide edge or the length edge of the second control board.

Advantageously, the first control board may be configured for electrical coupling with a capacitive touch sensing module. The first control board may be detachably couplable to a capacitive touch sensing module. The control electronics distributed over one or both of the first and second control boards may include touch sensing control electronics for controlling the capacitive touch sensing module.

The lighting assembly may comprise a plurality of the light emitting elements, a first lighting area and a second lighting area. Each of the first lighting area and the second lighting area may comprise one or more of the plurality of light emitting elements. The light emitting elements of the first lighting area are preferably distinct from the light emitting elements of the second lighting area. In one example, the first lighting area may partially or wholly surround the second lighting area. Preferably, the control electronics may be coupled to the plurality of light emitting elements and configured to selectively activate each of the first and second lighting areas to generate respective first and second light emissions.

In accordance with a second embodiment of the present disclosure, there is provided an aerosol-generating device for generating an inhalable aerosol from an aerosol-forming substrate. The aerosol-generating device may comprise an elongate housing extending in a longitudinal direction, a display window defined in the housing, and a control board assembly in accordance with any one of the variants discussed above. The display window may be formed from plastic or glass, or other light transmissive material. The control board assembly may be disposed within the elongate housing such that such that light emitted by the lighting assembly is visible via the display window. The provision of the hinge element facilitates the first and second control boards being folded to overlie each other in the folded state, thereby providing a compact volumetric footprint to the control board assembly. The compact volumetric footprint is beneficial in enabling the control board assembly to be fitted inside the housing of the aerosol-generating device.

Preferably, the aerosol-generating device may be configured to receive an aerosol-generating article comprising the aerosol-forming substrate. By way of example, the aerosol-generating device may comprise a cavity for receiving the aerosol-generating article.

The aerosol-generating device may comprise an electric heating arrangement. The electric heating arrangement may comprise a resistive heating arrangement or an inductive heating arrangement.

Conveniently, the elongate housing may be tubular in cross-section. The tubular cross-section may be a cylindrical cross-section. The elongate housing may be arcuate in cross-section. The compact volumetric footprint of the control board assembly in its folded state may facilitate ease of insertion of the assembly into the interior of the arcuate housing.

The aerosol-generating device may further comprise a light guide assembly configured to direct light generated by the lighting assembly to the display window.

Advantageously, the aerosol-generating device may further comprise a touch sensing module operably connected to touch sensing control electronics. Preferably, the touch sensing module may be configured to detect a touch input by a user on a touch interface of the aerosol-generating device.

Preferably, the touch sensing control electronics may form part of the control electronics distributed over one or both of the first control board and the second control board. Alternatively, the touch sensing control electronics may be distinct from the control electronics distributed over one or both of the first control board and the second control board.

Conveniently, the light guide assembly and the touch sensing module may be arranged between the lighting assembly and the display window. The light guide assembly and the touch sensing module may be successively arranged between the lighting assembly and the display window. By “successively arranged” is meant that the light guide assembly and the touch sensing module are arranged in sequence without being separated by intermediate structural elements.

Preferably, the touch sensing module may be configured to be responsive to two dimensional contact across a surface of the touch interface.

The touch interface may comprise at least a portion of the display window. In this manner, the display window is able to perform dual roles of allowing transmission of light from the lighting assembly and permitting touch-applied control inputs to be made to the aerosol-generating device.

Preferably, the touch sensing module may be a capacitive touch sensing module. The capacitive touch sensing module may comprise at least one electrically conductive layer. Advantageously, the touch sensing control electronics may be configured to: i) control the supply of energy to the electrically conductive layer to provide an electric charge over the electrically conductive layer; and ii) sense changes of electric charge of the electrically conductive layer associated with a touch event on the touch interface.

In one example, the touch sensing control electronics may be coupled to the electrically conductive layer so as to detect a change in capacitive coupling between different points or regions of the layer, the change associated with a touch event on the touch interface. This corresponds to a mutual capacitance mode of operation, which may allow multiple simultaneous contacts on the touch interface to be separately identified and the contact locations determined. In another example, the touch sensing control electronics may be coupled to the electrically conductive layer so as to detect a change in capacitance of a point or region of the layer with respect to ground, the change associated with a touch event on the touch interface. This corresponds to a self-capacitance mode of operation.

The touch sensing module may comprise one or more electrically conductive regions (for example, 1, 3, 5 or 6). The one or more electrically conductive regions may be arranged on an electrically insulating layer, or film. Each one of the electrically conductive regions may have a single or a plurality of electrical connections with a controller for sensing one or more touch inputs. The controller may be configured to determine a location of a touch event based on receiving an input from a specific one of the plurality of conductive regions.

The controller for sensing one or more touch inputs may comprise one or more switches each connected to a respective electrically conductive region and a sensing capacitor. The controller may be configured to transfer charge from a respective electrically conductive region to the sensing capacitor. The controller may be configured to detect a touch event based on the voltage across the sensing capacitor, optionally after one or more predetermined time intervals.

Each one of the electrically conductive regions may form a capacitance. The capacitance of each electrically conductive region may be up to 100 pF, between 5 pF and 50 pF, between 10 pF and 30 pF, or between 15 pF and 25 pF.

The electrically conductive regions may be distributed along an axis such that movements along that axis can be determined by the controller.

The electrically conductive regions may be distributed across a two-dimensional area along a first axis and a second axis such that movements along each of the axes can be determined by the controller.

The electronics may be configured to perform a function associated with a touch event at a particular electrically conductive region and/or to perform a function associated with a particular direction of movement (or gesture) performed by a user's finger.

The touch-sensing module may comprise an electrically conductive region surrounded by a plurality of separate regions.

Advantageously, the electrically conductive layer may be configured to be transmissive to the passage of light between opposing surfaces of the layer. In this manner, the electrically conductive layer may be positioned between the lighting assembly and the display window without hindering the transmission of light from the lighting assembly to the display window.

The display window may comprise or consist of a dielectric material. The electrically conductive layer may be in surface contact with an inner surface of the display window.

The electrically conductive layer may be a foil. The foil may comprise a mesh of electrically conductive filaments. The use of a meshed construction may facilitate transmission of light between opposing surfaces of the electrically conductive layer and the visibility of the transmitted light to a user through the display window.

Where the aerosol-generating device includes a light guide assembly, preferably, the electrically conductive layer may be arranged between and in surface contact with an arcuate outward-facing surface of the light guide assembly and an arcuate inward-facing surface of the display window. In this manner, the electrically conductive layer may be maintained in a stable position by virtue of being sandwiched between the arcuate outward-facing surface of the light guide assembly and the arcuate inward-facing surface of the display window. Advantageously, the arcuate outward-facing surface of the light guide assembly may be complementary in profile to the arcuate inward-facing surface of the display window.

The lighting assembly may comprise a plurality of the light emitting elements, a first lighting area and a second lighting area. Each of the first lighting area and the second lighting area may comprise one or more of the plurality of light emitting elements. The light emitting elements of the first lighting area are preferably distinct from the light emitting elements of the second lighting area. Preferably, the first lighting area may partially or wholly surround the second lighting area.

Advantageously, the control electronics may be coupled to the plurality of light emitting elements and configured to selectively activate each of the first and second lighting areas to generate respective first and second light emissions. The control electronics may be configured to: i) selectively activate one of the first and second lighting areas to generate a first predetermined light emission conveying first data indicative of a state of the aerosol-generating device; and ii) selectively activate the other of the first and second lighting areas to generate a second predetermined light emission conveying second data indicative of a state of the aerosol-generating device. The first data and the second data may be different from one another.

The first and second data may be indicative of any two of: a) a power source of the aerosol-generating device containing sufficient energy to complete a single usage session; b) a power source of the aerosol-generating device containing sufficient energy to complete two, three or more usage sessions; c) a power source of the aerosol-generating device containing a level of energy below a predetermined threshold level of energy; d) selection or activation of one of a first predetermined thermal profile and a second predetermined thermal profile, in which each of the first and second predetermined thermal profiles define a heating profile for heating of the aerosol-forming substrate by an electrical heating arrangement over a usage session, the first and second predetermined thermal profiles being different to each other; e) the aerosol-generating device being in one of a pause mode state or a reactivation state; f) selection or activation of a change in operational state of the aerosol-generating device; g) progression through a usage session; h) progression through a pre-heating phase in which an electrical heating arrangement is heated to a predetermined target temperature; i) the aerosol-generating device being in a locked state in which the device is prohibited from generating aerosol; j) the aerosol-generating device being in an unlocked state in which the device is permitted to generate aerosol; k) an entered PIN number for unlocking the device such that it is permitted to generate aerosol and/or an order of a PIN number in a sequence to be entered for unlocking the device such that it is permitted to generate aerosol; I) a type of a plurality of aerosol-generating articles being detected by the device; m) the aerosol-generating device being too hot to permit aerosol-generation; and n) the aerosol-generating device being too cold to permit aerosol-generation.

The control board assembly may be mounted on a chassis arranged to be slid inside the elongate housing. Advantageously, one of the chassis or an inner surface of the elongate housing may comprise one or more alignment grooves; and the other one of the chassis or the inner surface of the elongate housing comprise one or more alignment ridges for sliding within a respective one of the alignment grooves thus aligning the chassis with respect to the elongate housing.

In accordance with a third embodiment of the present disclosure, there is provided a method of assembling an aerosol-generating device. The method may comprise steps of:
providing an elongate tubular housing having a sidewall extending in a longitudinal direction, the sidewall comprising an aperture for a display window;
providing a control module, a lighting assembly and a touch sensing module, the touch sensing module configured for use in detecting a touch of a user, the lighting assembly arranged on a surface of the control module, the control module comprising control electronics for controlling at least one of the lighting assembly and the touch sensing module;
coupling the touch sensing module to the control module such that the touch sensing module overlies the lighting assembly, thereby forming an intermediate assembly module;
positioning the intermediate assembly module adjacent to an opening defined at one end of the elongate tubular housing; and
sliding the intermediate assembly module within the elongate tubular housing along the longitudinal direction to a predetermined location, the predetermined location corresponding to the lighting assembly being positioned adjacent to the aperture.

The control module may comprise a first control board and a second control board. The first and second control boards may preferably be coupled to each other by a hinge element. The first and second control boards and the hinge element may be as described in preceding paragraphs. The method may comprise a step of: folding one of the first and second control boards about the hinge element to overlie the other of the first and second control boards, wherein the folding step is performed prior to the step of sliding the intermediate assembly module within the elongate tubular housing.

In one example, the hinge element may extend between longitudinally-extending edges of the first control board and the second control board. The folding step may comprise one of the first and second control boards being folded about an axis extending generally parallel to a longitudinal axis of the other of the first and second control boards.

In another example, the hinge element may extend between laterally-extending edges of the first control board and the second control board. The folding step may comprise one of the first and second control boards being folded about an axis extending generally perpendicular to a longitudinal axis of the other of the first and second control boards.

The method may further comprise providing a separator element and disposing the separator element relative to the first and second control boards such that on completion of the folding step, the separator element is disposed between and spatially separates opposing inward-facing surfaces of the first control board and the second control board. The separator element may be as described in preceding paragraphs. The folding step may comprise folding one or both of the first and second control boards over the separator element.

The first control board may be formed from a first material composition and the second control board formed from a second material composition. The first material composition may preferably have a lower stiffness than the second material composition. The method may further comprise: providing a stiffening member having a stiffness greater than the first material composition, and overlaying the first control board onto a support surface of the stiffening member. The stiffening member may be as described in preceding paragraphs.

The touch sensing module may preferably comprise an electrically conductive layer. The step of coupling the touch sensing module to the control module may comprise arranging the electrically conductive layer over the lighting assembly.

In one example, the touch sensing module may be provided with the electrically conductive layer preformed into an arcuate profile. Alternatively, the step of coupling the touch sensing module to the control module may comprise deforming the electrically conductive layer into an arcuate profile. The arcuate profile of the electrically conductive layer may be such that on arranging the electrically conductive layer over the lighting assembly, an outward-facing surface of the electrically conductive layer defines a convex profile.

As described in preceding paragraphs, the electrically conductive layer may be a foil. The foil may comprise a mesh of electrically conductive filaments.

The method may further comprise steps of: providing a light guide assembly, positioning the light guide assembly over the lighting assembly, and arranging at least part of the touch sensing module over and in surface contact with an outward-facing surface of the light guide assembly. The light guide assembly may be described in preceding paragraphs.

Where the touch sensing module comprises an electrically conductive layer and the step of coupling the touch sensing module to the control module comprises arranging the electrically conductive layer over the lighting assembly, the step of arranging at least part of the touch sensing module over and in surface contact with an outward-facing surface of the light guide assembly may comprise arranging the electrically conductive layer over and in surface contact with the outward-facing surface of the light guide assembly. The outward-facing surface of the light guide assembly may be arcuate, preferably convex.

The elongate tubular housing may be provided with a display window preinstalled in the aperture. Preferably, after sliding the intermediate assembly module within the elongate tubular housing along the longitudinal direction to the predetermined location, an inward-facing surface of the display window may be in surface contact with at least part of the touch sensing module. Where the touch sensing module comprises an electrically conductive layer and the step of coupling the touch sensing module to the control module comprises arranging the electrically conductive layer over the lighting assembly, after sliding the intermediate assembly module within the elongate tubular housing along the longitudinal direction to the predetermined location, the inward-facing surface of the display window may be in surface contact with a surface of the electrically conductive layer.

The method may further comprise steps of: providing a display window, and installing the display window into the aperture. The display window may be as described in preceding paragraphs. The step of installing the display window into the aperture may be performed after the step of sliding the intermediate assembly module within the elongate tubular housing along the longitudinal direction to the predetermined location. Alternatively, the step of installing the display window into the aperture may be performed before the step of sliding the intermediate assembly module within the elongate tubular housing along the longitudinal direction to the predetermined location. Preferably, in the assembled aerosol-generating device resulting from the method, an inward-facing surface of the display window may be in surface contact with at least part of the touch sensing module. Where the touch sensing module includes an electrically conductive layer and the step of coupling the touch sensing module to the control module comprises arranging the electrically conductive layer over the lighting assembly, in the assembled aerosol-generating device, preferably the inward-facing surface of the display window may be in surface contact with a surface of the electrically conductive layer.

Preferably, the touch sensing module may be a capacitive touch sensing module.

In accordance with a fourth embodiment of the present disclosure, there is provided a method of assembling an aerosol-generating device. The method may comprise steps of:
providing an elongate tubular housing having a sidewall extending in a longitudinal direction, the sidewall comprising an aperture for a display window, a control module disposed inside the housing and positioned adjacent to the aperture, wherein a lighting assembly is arranged on a surface of the control module;
providing a touch sensing module, the touch sensing module configured for use in detecting a touch of a user;
inserting the touch sensing module through the aperture to couple with the control module such that the touch sensing module overlies the lighting assembly;
wherein the control module comprises control electronics for controlling at least one of the lighting assembly and the touch sensing module.

Preferably, the touch sensing module may comprise an electrically conductive layer, and the step of inserting the touch sensing module through the aperture comprise disposing the electrically conductive layer over the lighting assembly. In one example, the touch sensing module may be provided with the electrically conductive layer preformed into an arcuate profile. In another example, the step of inserting the touch sensing module through the aperture to couple with the control module may comprise deforming the electrically conductive layer into an arcuate profile. Preferably, the arcuate profile of the electrically conductive layer may be such that, on disposing the electrically conductive layer over the lighting assembly, an outward-facing surface of the electrically conductive layer defines a convex profile. As described in preceding paragraphs, the electrically conductive layer may be a foil. The foil may comprise a mesh of electrically conductive filaments.

The method may further comprise a step of providing a light guide assembly. The light guide assembly may be as described in preceding paragraphs.

The method may further comprise inserting the light guide assembly through the aperture to be positioned over the lighting assembly, wherein the inserting of the light guide assembly is performed separately to the step of inserting the touch sensing module through the aperture. Preferably, the step of inserting the touch sensing module through the aperture may be performed such that at least part of the touch sensing module is arranged over and in surface contact with an outward-facing surface of the light guide assembly. Where the touch sensing module comprises an electrically conductive layer and the step of inserting the touch sensing module through the aperture comprises disposing the electrically conductive layer over the lighting assembly, the step of inserting the touch sensing module through the aperture may preferably be performed such that the electrically conductive layer is arranged over and in surface contact with the outward-facing surface of the light guide assembly.

Conveniently, the light guide assembly and touch sensing module may be preassembled to each other outside of the housing to form a combined assembly module. The method may then further comprise inserting the combined assembly module through the aperture to overlie the lighting assembly. Preferably, in the combined assembly module, at least part of the touch sensing module is arranged over and in surface contact with an outward-facing surface of the light guide assembly. Where the touch sensing module comprises an electrically conductive layer and the step of inserting the touch sensing module through the aperture comprises disposing the electrically conductive layer over the lighting assembly, in the combined assembly module, the electrically conductive layer may preferably be arranged over and in surface contact with the outward-facing surface of the light guide assembly.

The outward-facing surface of the light guide assembly may be arcuate, preferably convex.

The method may further comprise steps of: providing a display window, and installing the display window in the aperture. The display window may be as described in preceding paragraphs. Preferably, the display window may be installed in the aperture such that an inward-facing surface of the display window is in surface contact with at least part of the touch sensing module. Where the touch sensing module comprises an electrically conductive layer and the step of inserting the touch sensing module through the aperture comprises disposing the electrically conductive layer over the lighting assembly, the display window may be installed in the aperture such that the inward-facing surface of the display window is in surface contact with the electrically conductive layer of the touch sensing module.

Preferably, the touch sensing module may be a capacitive touch sensing module.

As used herein, the term “aerosol-generating device” is used to describe a device that interacts with an aerosol-forming substrate to generate an aerosol. Preferably, the aerosol-generating device is a smoking device that interacts with an aerosol-forming substrate to generate an aerosol that is directly inhalable into a user's lungs thorough the user's mouth.

As used herein, the term “aerosol-generating article” refers to an article comprising an aerosol-forming substrate that is capable of releasing volatile compounds that can form an aerosol. An aerosol-generating article may be disposable.

As used herein, the term “aerosol-forming substrate” refers to a substrate consisting of or comprising an aerosol-forming material that is capable of releasing volatile compounds upon heating to generate an aerosol.

Preferably, the aerosol-forming substrate is a solid aerosol-forming substrate. However, the aerosol-forming substrate may comprise both solid and liquid components. Alternatively, the aerosol-forming substrate may be a liquid aerosol-forming substrate.

Preferably, the aerosol-forming substrate comprises nicotine. More preferably, the aerosol-forming substrate comprises tobacco. Alternatively or in addition, the aerosol-forming substrate may comprise a non-tobacco containing aerosol-forming material.

If the aerosol-forming substrate is a solid aerosol-forming substrate, the solid aerosol-forming substrate may comprise, for example, one or more of: powder, granules, pellets, shreds, strands, strips or sheets containing one or more of: herb leaf, tobacco leaf, tobacco ribs, expanded tobacco and homogenised tobacco.

Optionally, the solid aerosol-forming substrate may contain tobacco or non-tobacco volatile flavour compounds, which are released upon heating of the solid aerosol-forming substrate. The solid aerosol-forming substrate may also contain one or more capsules that, for example, include additional tobacco volatile flavour compounds or non-tobacco volatile flavour compounds and such capsules may melt during heating of the solid aerosol-forming substrate.

Optionally, the solid aerosol-forming substrate may be provided on or embedded in a thermally stable carrier. The carrier may take the form of powder, granules, pellets, shreds, strands, strips or sheets. The solid aerosol-forming substrate may be deposited on the surface of the carrier in the form of, for example, a sheet, foam, gel or slurry. The solid aerosol-forming substrate may be deposited on the entire surface of the carrier, or alternatively, may be deposited in a pattern in order to provide a non-uniform flavour delivery during use.

In a preferred embodiment, the aerosol-forming substrate comprises homogenised tobacco material. As used herein, the term “homogenised tobacco material” refers to a material formed by agglomerating particulate tobacco.

Preferably, the aerosol-forming substrate comprises a gathered sheet of homogenised tobacco material. As used herein, the term “sheet” refers to a laminar element having a width and length substantially greater than the thickness thereof. As used herein, the term “gathered” is used to describe a sheet that is convoluted, folded, or otherwise compressed or constricted substantially transversely to the longitudinal axis of the aerosol-generating article. Preferably, the aerosol-forming substrate comprises an aerosol former. As used herein, the term “aerosol former” is used to describe any suitable known compound or mixture of compounds that, in use, facilitates formation of an aerosol and that is substantially resistant to thermal degradation at the operating temperature of the aerosol-generating article.

Suitable aerosol-formers are known in the art and include, but are not limited to: polyhydric alcohols, such as propylene glycol, triethylene glycol, 1,3-butanediol and glycerine; esters of polyhydric alcohols, such as glycerol mono-, di-or triacetate; and aliphatic esters of mono-, di-or polycarboxylic acids, such as dimethyl dodecanedioate and dimethyl tetradecanedioate. Preferred aerosol formers are polyhydric alcohols or mixtures thereof, such as propylene glycol, triethylene glycol, 1,3-butanediol and, most preferred, glycerine.

The aerosol-forming substrate may comprise a single aerosol former. Alternatively, the aerosol-forming substrate may comprise a combination of two or more aerosol formers.

The invention is defined in the claims. However, below there is provided a non-exhaustive list of non-limiting examples. Any one or more of the features of these examples may be combined with any one or more features of another example, embodiment, or aspect described herein.

Example Ex1: A control board assembly for an aerosol-generating system, the assembly comprising:
a first elongate control board;
a second elongate control board;
a lighting assembly comprising one or more light emitting elements arranged on one or both of the first control board and the second control board;
control electronics distributed over one or both of the first control board and the second control board, at least a portion of the control electronics configured to control operation of the lighting assembly;
a hinge element coupling the first control board to the second control board;
the control board assembly having an unfolded state and a folded state, wherein in the folded state one of the first and second control boards is folded about the hinge element to overlie the other of the first and second control boards.

Example Ex2: A control board assembly according to Ex1, wherein the lighting assembly is arranged on an outward-facing surface of the first control board, the outward-facing surface associated with the folded state of the control board assembly.

Example Ex3: A control board assembly according to either one of Ex1 or Ex2, wherein the first control board and the second control board are arranged such that in the folded state opposing inward-facing surfaces of the first control board and the second control board are spatially separated from each other.

Example Ex4: A control board assembly according to Ex3, further comprising a separator element, wherein in the folded state the separator element is disposed between the opposing inward-facing surfaces of the first control board and the second control board.

Example Ex5: A control board assembly according to Ex4, wherein the separator element is formed of sheet metal.

Example Ex6: A control board assembly according to either one of Ex4 or Ex5, wherein the separator element contacts respective surface portions of the first control board and the second control board, the surface portions electrically insulated from the control electronics.

Example Ex7: A control board assembly according to any one of Ex1 to Ex6, wherein the first control board is formed from a first material composition and the second control board is formed from a second material composition, the first material composition having a lower stiffness than the second material composition.

Example Ex8: A control board assembly according to Ex7, further comprising a stiffening member, the stiffening member having a stiffness greater than the first material composition, the first control board overlaid on a support surface of the stiffening member.

Example Ex9: A control board assembly according to Ex8, wherein in the folded state the stiffening member is disposed between opposing inward-facing surfaces of the first control board and the second control board.

Example Ex10: A control board assembly according to either one of Ex8 or Ex9, wherein the support surface of the stiffening member is a planar surface.

Example Ex11: A control board assembly according to any one of Ex1 to Ex10, wherein the hinge element is formed of a material composition having a lower stiffness than a material composition of the second control board.

Example Ex12: A control board assembly according to any one of Ex1 to Ex11, wherein the hinge element is formed of a resilient and/or bendable material.

Example Ex13: A control board assembly according to any one of Ex1 to Ex12, wherein the hinge element is configured to provide an electrically conductive pathway between the first control board and the second control board.

Example Ex14: A control board assembly according to Ex13, wherein the electrical conductive pathway comprises one or more electrically conductive tracks overlaid on or embedded in the hinge element.

Example Ex15: A control board assembly according to any one of Ex1 to Ex14, wherein the hinge element is an extended integral portion of the first control board.

Example Ex16: A control board assembly according to Ex15, wherein the extended integral portion is detachably coupled to the second control board.

Example Ex17: A control board assembly according to Ex16, wherein the detachable coupling between the extended integral portion and the second control board comprises a push-fit connection interface.

Example Ex18: A control board assembly according to any one of Ex1 to Ex14, wherein the hinge element is structurally distinct from the first control board and the second control board, a first end of the hinge element coupled to the first control board and a second end of the hinge element coupled to the second control board.

Example Ex19: A control board assembly according to Ex18, wherein the coupling between the hinge element and one or both of the first control board and the second control board is a detachable coupling.

Example Ex20: A control board assembly according to Ex19, wherein the detachable coupling comprises a push-fit connection interface.

Example Ex21: A control board assembly according to any one of Ex1 to Ex20, wherein the hinge element extends between longitudinally-extending edges of the first control board and the second control board.

Example Ex22: A control board assembly according to Ex21, wherein the hinge element is configured such that transition from the unfolded state to the folded state comprises one of the first and second control boards being folded about an axis extending generally parallel to a longitudinal axis of the other of the first and second control boards.

Example Ex23: A control board assembly according to any one of Ex1 to Ex20, wherein the hinge element extends between laterally-extending edges of the first control board and the second control board.

Example Ex24: A control board assembly according to Ex23, wherein the hinge element is configured such that transition from the unfolded state to the folded state comprises one of the first and second control boards being folded about an axis extending generally perpendicular to a longitudinal axis of the other of the first and second control boards.

Example Ex25: A control board assembly according to any one of Ex1 to Ex24, wherein the first control board is configured for electrical coupling with a capacitive touch sensing module.

Example Ex26: A control board assembly according to Ex25, wherein the first control board is detachably couplable to a capacitive touch sensing module.

Example Ex27: A control board assembly according to any one of Ex1 to Ex26, wherein the lighting assembly comprises a plurality of the light emitting elements, a first lighting area and a second lighting area, each of the first lighting area and the second lighting area comprising one or more of the plurality of light emitting elements.

Example Ex28: A control board assembly according to Ex27, wherein the first lighting area partially or wholly surrounds the second lighting area.

Example Ex29: A control board assembly according to either one of Ex27 or Ex28, wherein the control electronics are coupled to the plurality of light emitting elements and are configured to selectively activate each of the first and second lighting areas to generate respective first and second light emissions.

Example Ex30: An aerosol-generating device for generating an inhalable aerosol from an aerosol-forming substrate, the aerosol-generating device comprising:
an elongate housing extending in a longitudinal direction;
a display window defined in the housing;
a control board assembly in accordance with any one of Ex1 to Ex29, wherein the control board assembly is disposed within the elongate housing such that such that light emitted by the lighting assembly is visible via the display window.

Example Ex31: An aerosol-generating device according to Ex30, wherein the aerosol-generating device is configured to receive an aerosol-generating article comprising the aerosol-forming substrate.

Example Ex32: An aerosol-generating device according to either one of Ex30 or Ex31, wherein the elongate housing is tubular in cross-section.

Example Ex33: An aerosol-generating device according to Ex32, wherein the tubular cross-section is a cylindrical cross-section.

Example Ex34: An aerosol-generating device according to any one of Ex30 to Ex33, wherein the elongate housing is arcuate in cross-section.

Example Ex35: An aerosol-generating device according to any one of Ex30 to Ex34, further comprising a light guide assembly configured to direct light generated by the lighting assembly to the display window.

Example Ex36: An aerosol-generating device according to any one of Ex30 to Ex35, further comprising a touch sensing module operably connected to touch sensing control electronics, the touch sensing module configured to detect a touch input by a user on a touch interface of the aerosol-generating device.

Example Ex36a: An aerosol-generating device according to Ex36, wherein the touch sensing module comprises one or more electrically conductive regions (for example, 1, 3, 5 or 6).

Example Ex36b: An aerosol-generating device according to Ex36a, wherein the one or more electrically conductive regions are arranged on an electrically insulating layer, or film.

Example Ex36c: An aerosol-generating device according to Ex36a or Ex36b, wherein each one of the electrically conductive regions has a single or a plurality of electrical connections with the touch sensing control electronics for sensing one or more touch inputs.

Example Ex36d: An aerosol-generating device according to Ex36c, wherein the touch sensing control electronics is configured to determine a location of a touch event based on receiving an input from a specific one of the plurality of conductive regions.

Example Ex36e: An aerosol-generating device according to any one of Ex36a to Ex36d, wherein the electrically conductive regions are distributed along an axis such that movements along that axis can be determined by the touch sensing control electronics.

Example Ex36f: An aerosol-generating device according to any one of Ex36a to Ex36e, wherein the electrically conductive regions are distributed across a two-dimensional area along a first axis and a second axis such that movements along each of the axes can be determined by the touch sensing control electronics.

Example Ex36g: An aerosol-generating device according to any one of Ex36a to Ex36f, wherein the touch sensing control electronics is configured to perform a function associated with a touch event at a particular electrically conductive region and/or to perform a function associated with a particular direction of movement (or gesture) performed by a user's finger.

Example Ex36h: An aerosol-generating device according to any one of Ex36a to Ex36g, wherein the touch-sensing module comprises an electrically conductive region surrounded by a plurality of separate regions.

Example Ex37: An aerosol-generating device according to Ex36, wherein the touch sensing control electronics forms part of the control electronics distributed over one or both of the first control board and the second control board.

Example Ex38: An aerosol-generating device according to Ex36, wherein the touch sensing control electronics are distinct from the control electronics distributed over one or both of the first control board and the second control board.

Example Ex39: An aerosol-generating device according to Ex35 in combination with any one of Ex36 to Ex38, wherein the light guide assembly and the touch sensing module are successively arranged between the lighting assembly and the display window.

Example Ex40: An aerosol-generating device according to any one of Ex36 to Ex39, wherein the touch sensing module is configured to be responsive to two dimensional contact across a surface of the touch interface.

Example Ex41: An aerosol-generating device according to any one of Ex36 to Ex40, wherein the touch interface comprises at least a portion of the display window.

Example Ex42: An aerosol-generating device according to any one of Ex36 to Ex41, wherein the touch sensing module is a capacitive touch sensing module.

Example Ex43: An aerosol-generating device according to Ex42, wherein the capacitive touch sensing module comprises at least one electrically conductive layer.

Example Ex44: An aerosol-generating device according to Ex43, wherein the touch sensing control electronics are configured to:
control the supply of energy to the electrically conductive layer to provide an electric charge over the electrically conductive layer; and
sense changes of electric charge of the electrically conductive layer associated with a touch event on the touch interface.

Example Ex45: An aerosol-generating device according to either one of Ex43 or Ex44, wherein the touch sensing control electronics are coupled to the electrically conductive layer so as to detect a change in capacitive coupling between different points or regions of the layer, the change associated with a touch event on the touch interface.

Example Ex46: An aerosol-generating device according to any one of Ex43 to Ex45, wherein the touch sensing control electronics are coupled to the electrically conductive layer so as to detect a change in capacitance of a point or region of the layer with respect to ground, the change associated with a touch event on the touch interface.

Example Ex47: An aerosol-generating device according to any one of Ex43 to Ex46, wherein the electrically conductive layer is configured to be transmissive to the passage of light between opposing surfaces of the layer.

Example Ex48: An aerosol generating device according to any one of Ex43 to Ex47, wherein the display window comprises or consists of a dielectric material, and the electrically conductive layer is in surface contact with an inner surface of the display window.

Example Ex49: An aerosol-generating device according to any one of Ex43 to Ex48, wherein the electrically conductive layer is a foil.

Example Ex50: An aerosol-generating device according to Ex49, wherein the foil comprises a mesh of electrically conductive filaments.

Example Ex51: An aerosol-generating device according to Ex35 in combination with any one of Ex43 to Ex50, wherein the electrically conductive layer is arranged between and in surface contact with an arcuate outward-facing surface of the light guide assembly and an arcuate inward-facing surface of the display window.

Example Ex52: An aerosol-generating device according to Ex51, wherein the arcuate outward-facing surface of the light guide assembly is complementary in profile to the arcuate inward-facing surface of the display window.

Example Ex53: An aerosol-generating device according to any one of Ex1 to Ex52, wherein the lighting assembly comprises a plurality of the light emitting elements, a first lighting area and a second lighting area, each of the first lighting area and the second lighting area comprising one or more of the plurality of light emitting elements.

Example Ex54: An aerosol-generating device according to Ex53, wherein the first lighting area partially or wholly surrounds the second lighting area.

Example Ex55: An aerosol-generating device according to either one of Ex53 or Ex54, wherein the control electronics are coupled to the plurality of light emitting elements and configured to selectively activate each of the first and second lighting areas to generate respective first and second light emissions.

Example Ex56: An aerosol-generating device according to Ex55, wherein the control electronics are configured to:
i) selectively activate one of the first and second lighting areas to generate a first predetermined light emission conveying first data indicative of a state of the aerosol-generating device;
and
ii) selectively activate the other of the first and second lighting areas to generate a second predetermined light emission conveying second data indicative of a state of the aerosol-generating device, wherein the first data and the second data are different from one another.

Example Ex57: An aerosol-generating device according to Ex56, wherein the first and second data are indicative of any two of:
a) a power source of the aerosol-generating device containing sufficient energy to complete a single usage session;
b) a power source of the aerosol-generating device containing sufficient energy to complete two, three or more usage sessions;
c) a power source of the aerosol-generating device containing a level of energy below a predetermined threshold level of energy;
d) selection or activation of one of a first predetermined thermal profile and a second predetermined thermal profile, wherein each of the first and second predetermined thermal profiles define a heating profile for heating of the aerosol-forming substrate by an electrical heating arrangement over a usage session, the first and second predetermined thermal profiles being different to each other;
e) the aerosol-generating device being in one of a pause mode state or a reactivation state;
f) selection or activation of a change in operational state of the aerosol-generating device;
g) progression through a usage session;
h) progression through a pre-heating phase in which an electrical heating arrangement is heated to a predetermined target temperature;
i) the aerosol-generating device being in a locked state in which the device is prohibited from generating aerosol;
j) the aerosol-generating device being in an unlocked state in which the device is permitted to generate aerosol;
k) an entered PIN number for unlocking the device such that it is permitted to generate aerosol and/or an order of a PIN number in a sequence to be entered for unlocking the device such that it is permitted to generate aerosol;
l) a type of a plurality of aerosol-generating articles being detected by the device;
m) the aerosol-generating device being too hot to permit aerosol-generation; and
n) the aerosol-generating device being too cold to permit aerosol-generation.

Example Ex57a: An aerosol-generating device according to any one of Ex30 to Ex57, wherein the control board assembly is mounted on a chassis arranged to be slid inside the elongate housing.

Example Ex57b: An aerosol-generating device according to Ex57a, wherein one of the chassis or an inner surface of the elongate housing comprises one or more alignment grooves; and the other one of the chassis or the inner surface of the elongate housing comprise one or more alignment ridges for sliding within a respective one of the alignment grooves thus aligning the chassis with respect to the elongate housing.

Example Ex58: A method of assembling an aerosol-generating device, the method comprising steps of:
providing an elongate tubular housing having a sidewall extending in a longitudinal direction, the sidewall comprising an aperture for a display window;
providing a control module, a lighting assembly and a touch sensing module, the touch sensing module configured for use in detecting a touch of a user, the lighting assembly arranged on a surface of the control module, the control module comprising control electronics for controlling at least one of the lighting assembly and the touch sensing module;
coupling the touch sensing module to the control module such that the touch sensing module overlies the lighting assembly, thereby forming an intermediate assembly module;
positioning the intermediate assembly module adjacent to an opening defined at one end of the elongate tubular housing;
sliding the intermediate assembly module within the elongate tubular housing along the longitudinal direction to a predetermined location, the predetermined location corresponding to the lighting assembly being positioned adjacent to the aperture.

Example Ex59: A method according to Ex58, wherein the control module comprises a first control board and a second control board, the first and second control boards coupled to each other by a hinge element, wherein the method comprises a step of:
folding one of the first and second control boards about the hinge element to overlie the other of the first and second control boards, wherein the folding step is performed prior to the step of sliding the intermediate assembly module within the elongate tubular housing.

Example Ex60: A method according to Ex59, wherein the hinge element extends between longitudinally-extending edges of the first control board and the second control board, the folding step comprising one of the first and second control boards being folded about an axis extending generally parallel to a longitudinal axis of the other of the first and second control boards.

Example Ex61: A method according to Ex59, wherein the hinge element extends between laterally-extending edges of the first control board and the second control board, the folding step comprising one of the first and second control boards being folded about an axis extending generally perpendicular to a longitudinal axis of the other of the first and second control boards.

Example Ex62: A method according to any one of Ex59 to Ex61, further comprising providing a separator element and disposing the separator element relative to the first and second control boards such that on completion of the folding step, the separator element is disposed between and spatially separates opposing inward-facing surfaces of the first control board and the second control board.

Example Ex63: A method according to Ex62, wherein the folding step comprises folding one or both of the first and second control boards over the separator element.

Example Ex64: A method according to any one of Ex58 to Ex63, wherein the first control board is formed from a first material composition and the second control board is formed from a second material composition, the first material composition having a lower stiffness than the second material composition, the method further comprising:
providing a stiffening member having a stiffness greater than the first material composition; and
overlaying the first control board onto a support surface of the stiffening member.

Example Ex65: A method according to any one of Ex58 to Ex64, wherein the touch sensing module comprises an electrically conductive layer, and the step of coupling the touch sensing module to the control module comprises arranging the electrically conductive layer over the lighting assembly.

Example Ex66: A method according to Ex65, wherein the touch sensing module is provided with the electrically conductive layer preformed into an arcuate profile.

Example Ex67: A method according to Ex65, wherein the step of coupling the touch sensing module to the control module comprises deforming the electrically conductive layer into an arcuate profile.

Example Ex68: A method according to either one or Ex66 or Ex67, wherein the arcuate profile of the electrically conductive layer is such that on arranging the electrically conductive layer over the lighting assembly, an outward-facing surface of the electrically conductive layer defines a convex profile.

Example Ex69: A method according to any one of Ex65 to Ex68, wherein the electrically conductive layer is a foil.

Example Ex70: A method according to Ex69, wherein the foil comprises a mesh of electrically conductive filaments.

Example Ex71: A method according to any one of Ex58 to Ex70, further comprising steps of:
providing a light guide assembly;
positioning the light guide assembly over the lighting assembly; and
arranging at least part of the touch sensing module over and in surface contact with an outward-facing surface of the light guide assembly.

Example Ex72: A method according to Ex65 in combination with Ex71, wherein the step of arranging at least part of the touch sensing module over and in surface contact with an outward-facing surface of the light guide assembly comprises arranging the electrically conductive layer over and in surface contact with the outward-facing surface of the light guide assembly.

Example Ex73: A method according to Ex72, wherein the outward-facing surface of the light guide assembly is arcuate, preferably convex.

Example Ex74: A method according to any one of Ex58 to Ex73, wherein the elongate tubular housing is provided with a display window preinstalled in the aperture.

Example Ex75: A method according to Ex74, wherein after sliding the intermediate assembly module within the elongate tubular housing along the longitudinal direction to the predetermined location, an inward-facing surface of the display window is in surface contact with at least part of the touch sensing module.

Example Ex76: A method according to Ex65 in combination with Ex75, wherein after sliding the intermediate assembly module within the elongate tubular housing along the longitudinal direction to the predetermined location, the inward-facing surface of the display window is in surface contact with a surface of the electrically conductive layer.

Example Ex77: A method according to any one of Ex58 to Ex73, further comprising steps of:
providing a display window; and
installing the display window into the aperture.

Example Ex78: A method according to Ex77, wherein the step of installing the display window into the aperture is performed after the step of sliding the intermediate assembly module within the elongate tubular housing along the longitudinal direction to the predetermined location.

Example Ex79: A method according to Ex77, wherein the step of installing the display window into the aperture is performed before the step of sliding the intermediate assembly module within the elongate tubular housing along the longitudinal direction to the predetermined location.

Example Ex80: A method according to one of Ex77 to Ex79, wherein in the assembled aerosol-generating device, an inward-facing surface of the display window is in surface contact with at least part of the touch sensing module.

Example Ex81: A method according to Ex65 in combination with Ex80, wherein in the assembled aerosol-generating device, the inward-facing surface of the display window is in surface contact with a surface of the electrically conductive layer.

Example Ex82: A method according to any one of Ex58 to Ex81, wherein the touch sensing module is a capacitive touch sensing module.

Example Ex82a: A method according to any one of Ex58 to Ex82, wherein the intermediate assembly module comprises a chassis.

Example Ex82b: A method according to Ex82a, wherein one of the chassis or an inner surface of the elongate housing comprises one or more alignment grooves; and the other one of the chassis or the inner surface of the elongate housing comprises one or more alignment ridges for sliding within a respective one of the alignment grooves thus aligning the chassis with respect to the elongate housing.

Example Ex83: A method of assembling an aerosol-generating device, the method comprising steps of:
providing an elongate tubular housing having a sidewall extending in a longitudinal direction, the sidewall comprising an aperture for a display window, a control module disposed inside the housing and positioned adjacent to the aperture, wherein a lighting assembly is arranged on a surface of the control module;
providing a touch sensing module, the touch sensing module configured for use in detecting a touch of a user;
inserting the touch sensing module through the aperture to couple with the control module such that the touch sensing module overlies the lighting assembly;
wherein the control module comprises control electronics for controlling at least one of the lighting assembly and the touch sensing module.

Example Ex84: A method according to Ex83, wherein the touch sensing module comprises an electrically conductive layer, the step of inserting the touch sensing module through the aperture comprising disposing the electrically conductive layer over the lighting assembly.

Example Ex85: A method according to Ex84, wherein the touch sensing module is provided with the electrically conductive layer preformed into an arcuate profile.

Example Ex86: A method according to Ex84, wherein the step of inserting the touch sensing module through the aperture to couple with the control module comprises deforming the electrically conductive layer into an arcuate profile.

Example Ex87: A method according to either one of Ex85 or Ex86, wherein the arcuate profile of the electrically conductive layer is such that, on disposing the electrically conductive layer over the lighting assembly, an outward-facing surface of the electrically conductive layer defines a convex profile.

Example Ex88: A method according to any one of Ex84 to Ex87, wherein the electrically conductive layer is a foil.

Example Ex89: A method according to Ex88, wherein the foil comprises a mesh of electrically conductive filaments.

Example Ex90: A method according to any one of Ex83 to Ex89, further comprising providing a light guide assembly.

Example Ex91: A method according to Ex90, further comprising inserting the light guide assembly through the aperture to be positioned over the lighting assembly, wherein the inserting of the light guide assembly is performed separately to the step of inserting the touch sensing module through the aperture.

Example Ex92: A method according to Ex91, wherein the step of inserting the touch sensing module through the aperture is performed such that at least part of the touch sensing module is arranged over and in surface contact with an outward-facing surface of the light guide assembly.

Example Ex93: A method according to Ex84 in combination with Ex92, wherein the step of inserting the touch sensing module through the aperture is performed such that the electrically conductive layer is arranged over and in surface contact with the outward-facing surface of the light guide assembly.

Example Ex94: A method according to Ex90, wherein the light guide assembly and touch sensing module are preassembled to each other outside of the housing to form a combined assembly module, the method further comprising inserting the combined assembly module through the aperture to overlie the lighting assembly.

Example Ex95: A method according to Ex94, wherein in the combined assembly module, at least part of the touch sensing module is arranged over and in surface contact with an outward-facing surface of the light guide assembly.

Example Ex96: A method according to Ex84 in combination with Ex95, wherein in the combined assembly module, the electrically conductive layer is arranged over and in surface contact with the outward-facing surface of the light guide assembly.

Example Ex97: A method according to any one of Ex92, Ex93, Ex95 or Ex96, wherein the outward-facing surface of the light guide assembly is arcuate, preferably convex.

Example Ex98: A method according to any one of Ex83 to Ex97, further comprising steps of:
providing a display window; and
installing the display window in the aperture.

Example Ex99: A method according to Ex98, wherein the display window is installed in the aperture such that an inward-facing surface of the display window is in surface contact with at least part of the touch sensing module.

Example Ex100: A method according to Ex84 in combination with Ex99, wherein the display window is installed in the aperture such that the inward-facing surface of the display window is in surface contact with the electrically conductive layer of the touch sensing module.

Example Ex101: A method according to any one of Ex83 to Ex100, wherein the touch sensing module is a capacitive touch sensing module.

Examples will now be further described with reference to the figures in which:

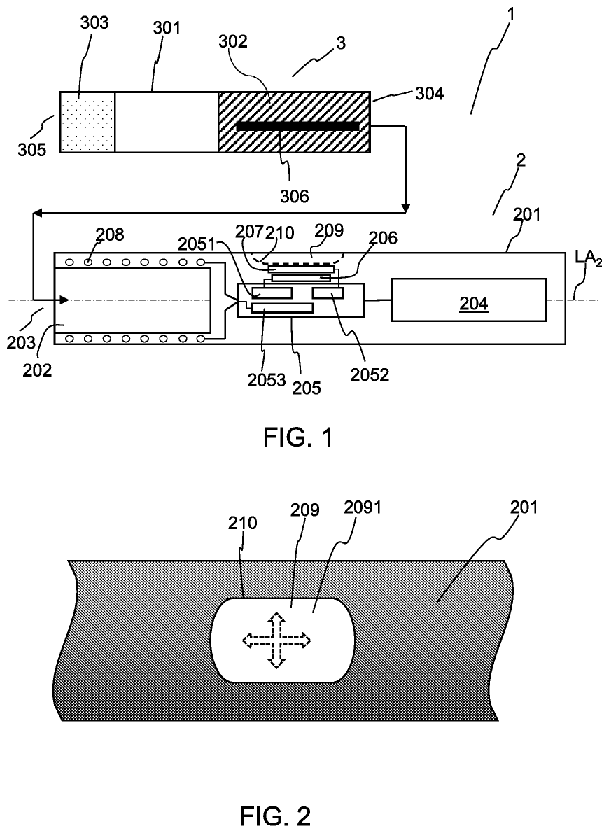

FIG. 1 shows a schematic illustration of a first embodiment of an aerosol-generating system according to the present disclosure.

FIG. 2 shows a schematic illustration of a touch interface defined by a display window of an aerosol-generating device of the aerosol-generating system of FIG. 1.

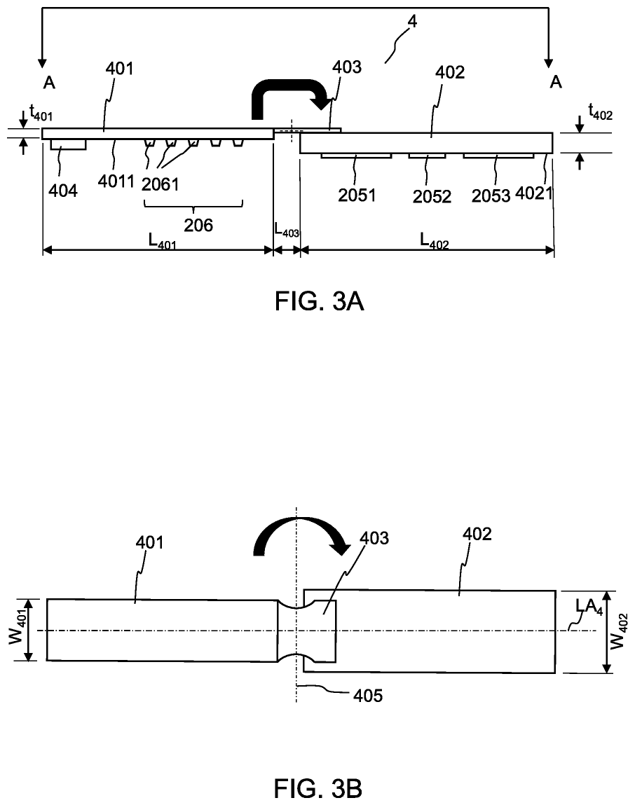

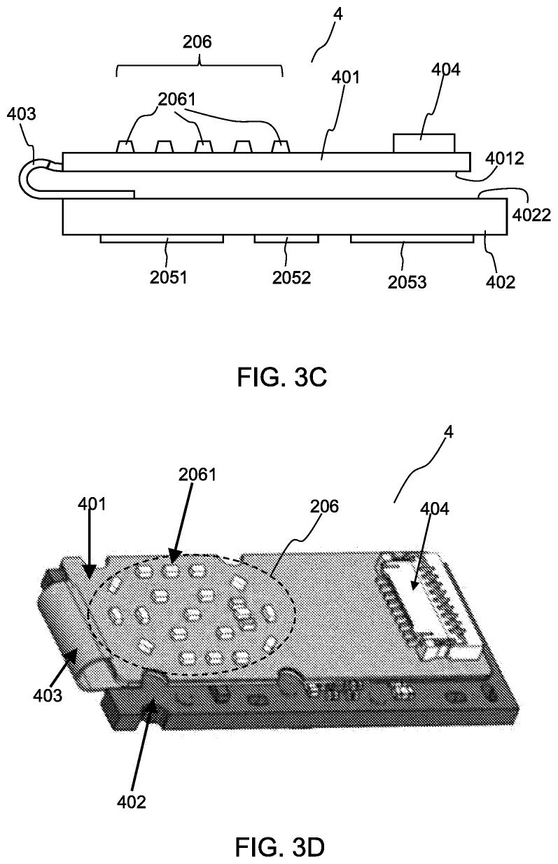

FIG. 3A shows a schematic side elevation illustration of a first embodiment of a control board assembly according to the present disclosure, the control board assembly being in an unfolded state.

FIG. 3B shows a schematic plan illustration of the control board assembly of FIG. 3A, in the direction of A-A of FIG. 3A.

FIG. 3C shows a schematic side elevation illustration of the control board assembly of FIGS. 3A and 3B after transition from the unfolded state to a folded state.

FIG. 3D shows a schematic perspective illustration from above of the control board assembly of FIG. 3C.

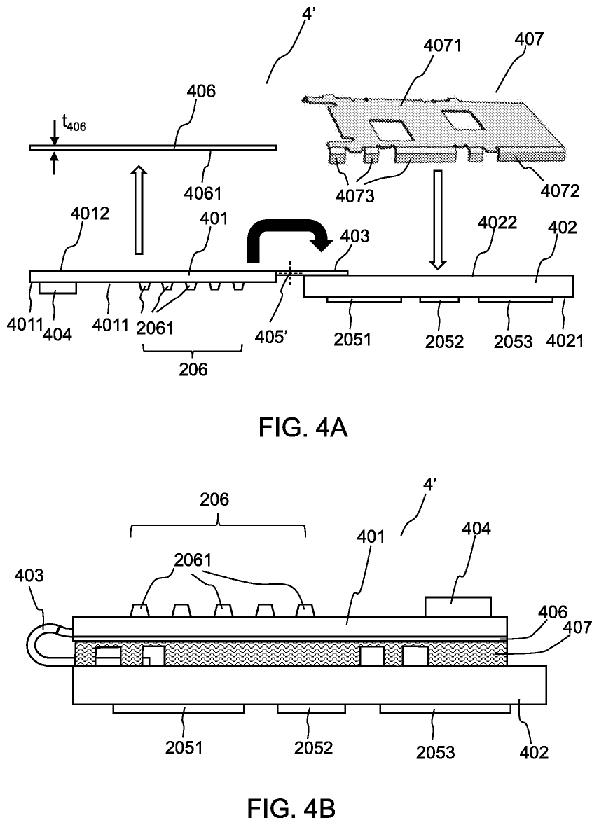

FIG. 4A shows a schematic side elevation illustration of a second embodiment of a control board assembly according to the present disclosure, the control board assembly being in an unfolded state.

FIG. 4B shows a schematic side elevation illustration of the control board assembly of FIG. 4A after transition from the unfolded state to a folded state.

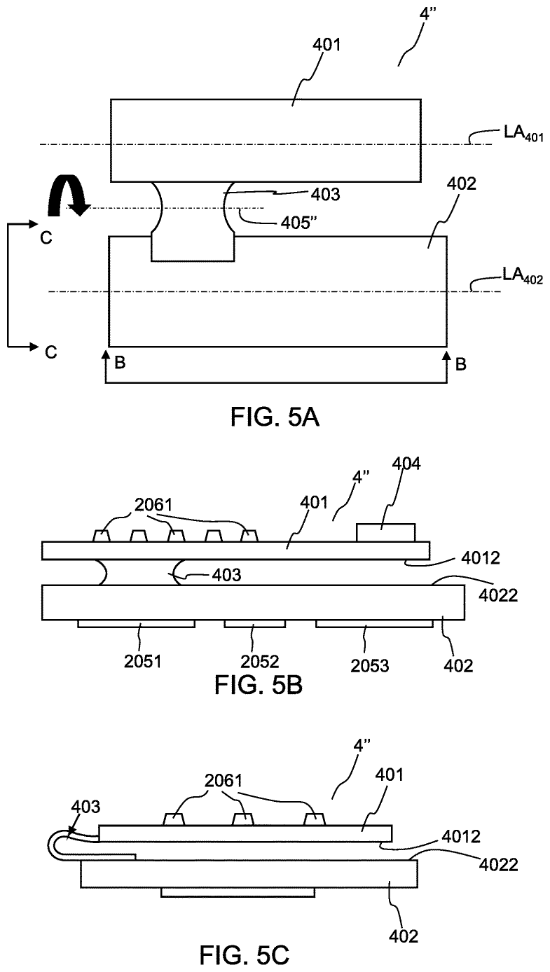

FIG. 5A shows a schematic plan illustration of a third embodiment of a control board assembly according to the present disclosure, the control board assembly being in an unfolded state.

FIG. 5B shows a schematic side elevation illustration of the control board assembly of FIG. 5A, in the direction of B-B of FIG. 5A, after transition from the unfolded state to a folded state.

FIG. 5C shows a schematic side elevation illustration of the control board assembly of FIG. 5A, in the direction of C-C of FIG. 5A, after transition from the unfolded state to the folded state.

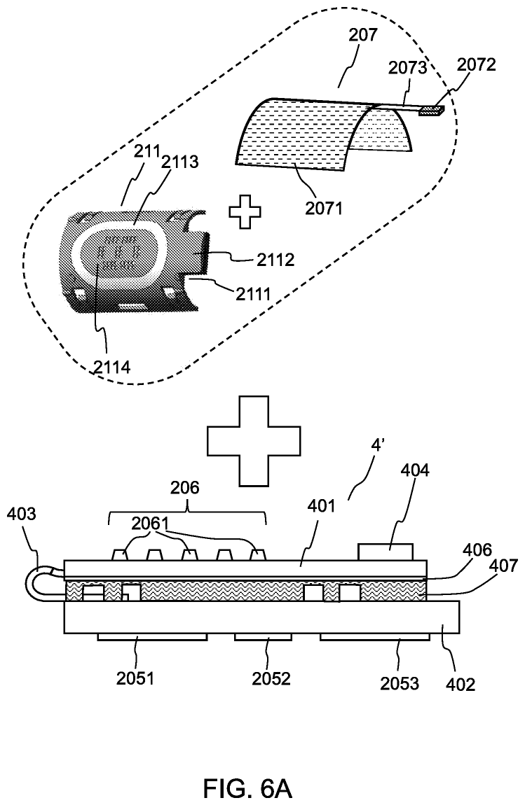

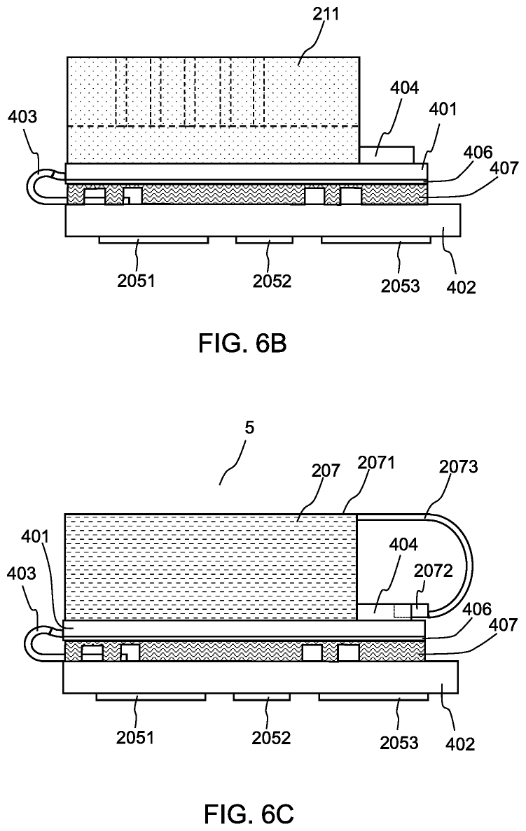

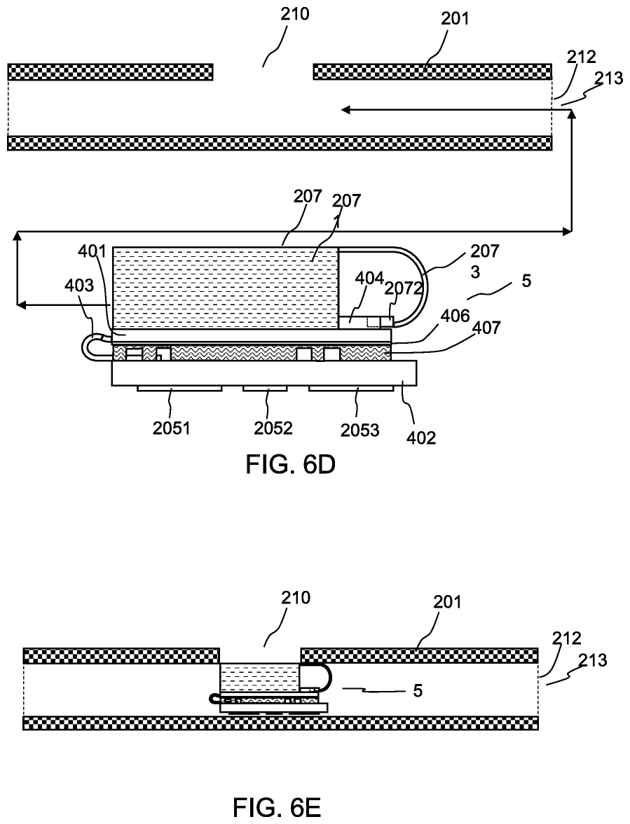

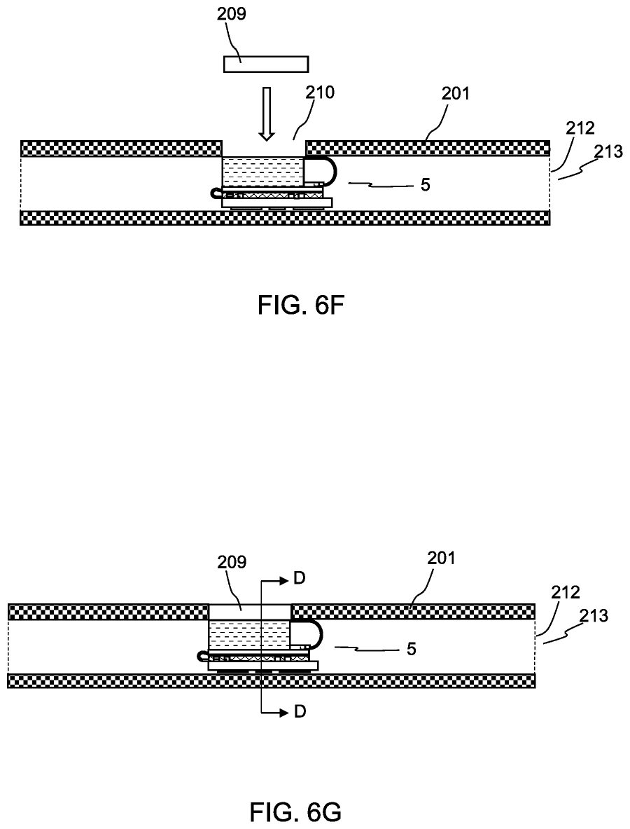

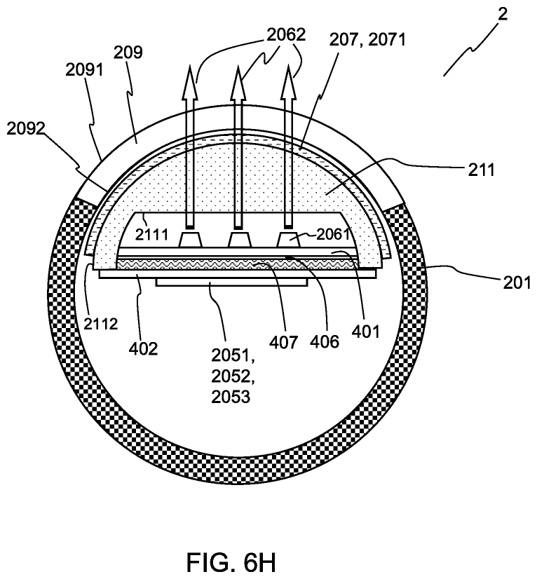

FIG. 6A shows a schematic side elevation illustration of the folded control board assembly of FIG. 4B, along with a separate light guide assembly and a separate touch sensing module.

FIG. 6B shows a schematic side elevation illustration of the control board assembly in a state subsequent to that shown in FIG. 6A, after the light guide assembly has been mounted to the control board assembly.

FIG. 6C shows a schematic side elevation illustration of the control board assembly in a state subsequent to that shown in FIG. 6B, after the touch sensing module has been positioned over the light guide assembly to form an intermediate assembly module.

FIG. 6D shows a schematic illustration of an elongate cylindrical housing of an aerosol-generating device, with the figure illustrating how the intermediate assembly module of FIG. 6C is to be inserted into an opening located at an end of the housing.

FIG. 6E shows a schematic illustration of the housing of the aerosol-generating device after the intermediate assembly module has been slid to a predetermined location within the housing.

FIG. 6F shows a schematic illustration of a display window being installed in an aperture defined in the housing.

FIG. 6G shows a schematic illustration of the aerosol-generating device after installation of the display window in the aperture.

FIG. 6H shows a schematic cross-sectional illustration through section D-D of the aerosol-generating device of FIG. 6G.

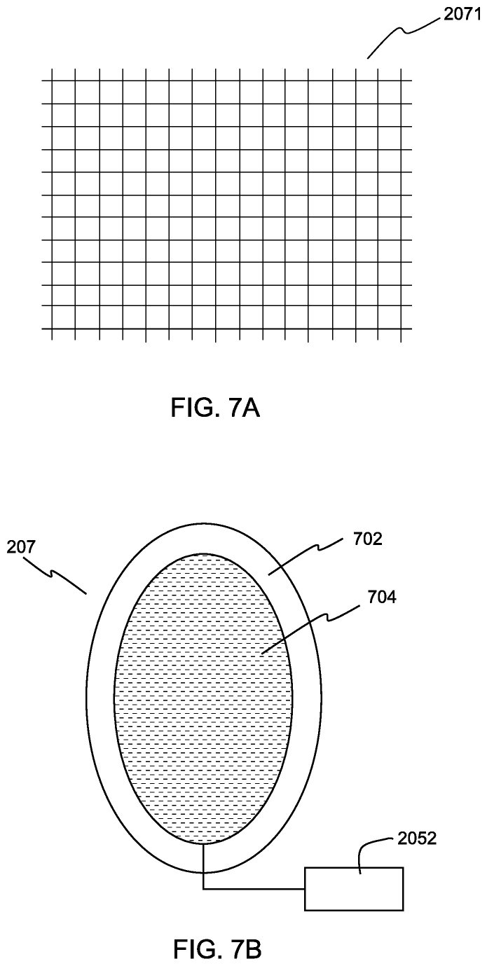

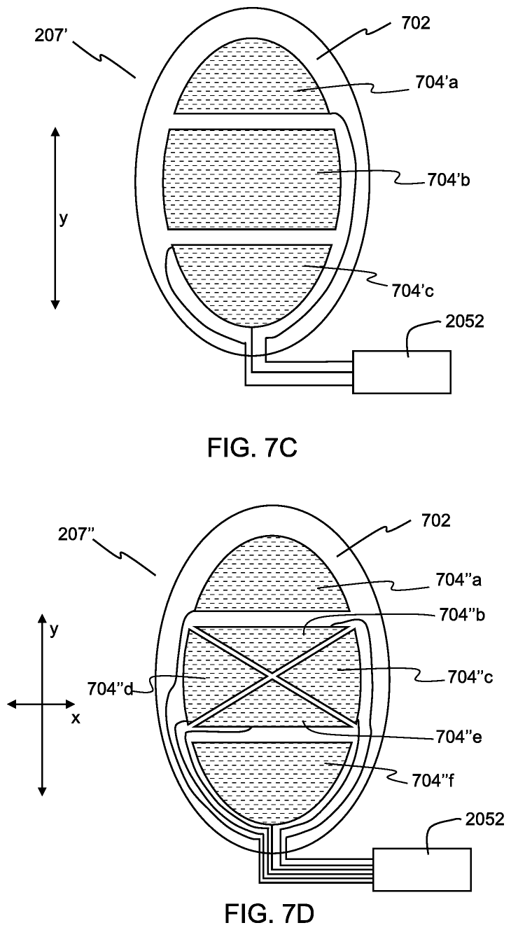

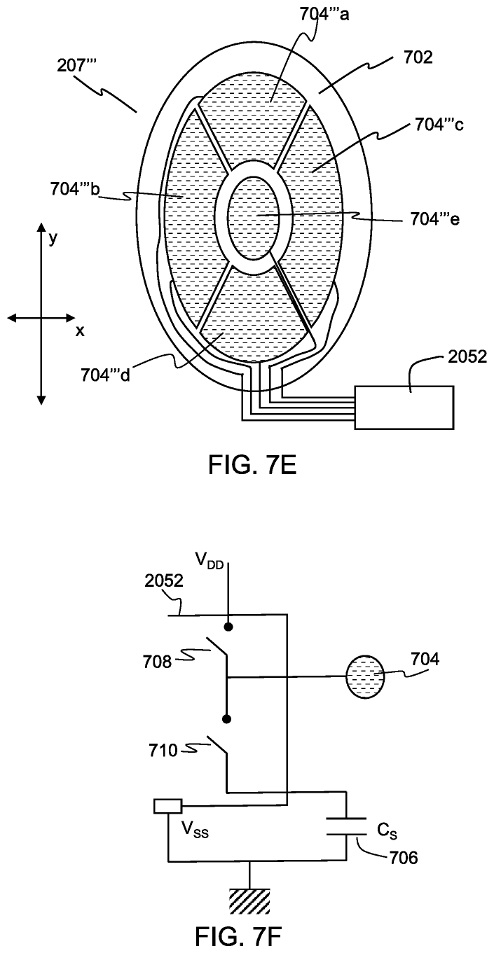

FIG. 7A shows a schematic plan illustration of a mesh for use in forming a capacitive touch foil mesh of the touch sensing module (also referred to herein as a touch sensor) illustrated in FIG. 6A.

FIGS. 7B to 7E illustrate examples of touch sensing modules, also referred to herein as touch sensors.

FIG. 7F illustrates a circuit for detecting touch events.

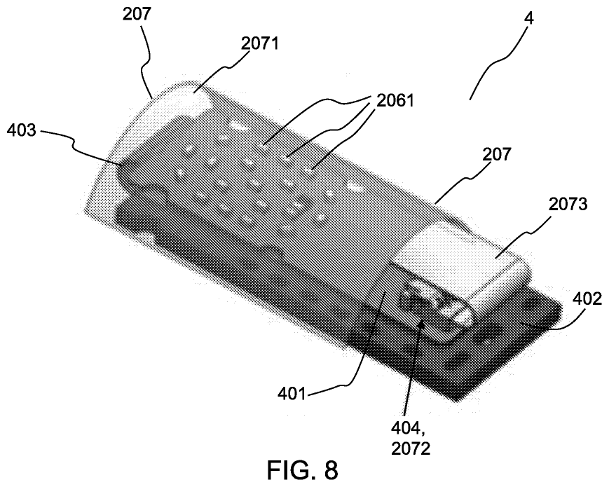

FIG. 8 shows a schematic perspective illustration from above of the control board assembly of FIG. 3D, with a touch sensing module arranged over and coupled to the control board assembly.

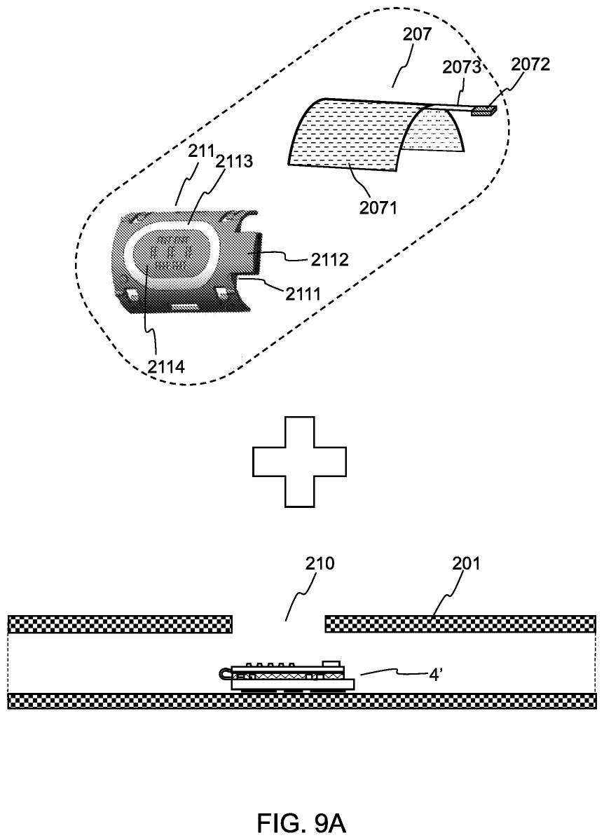

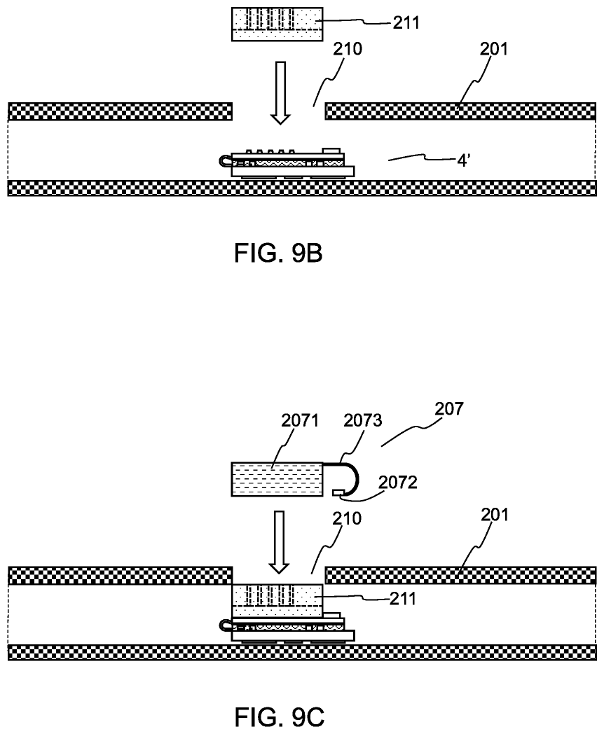

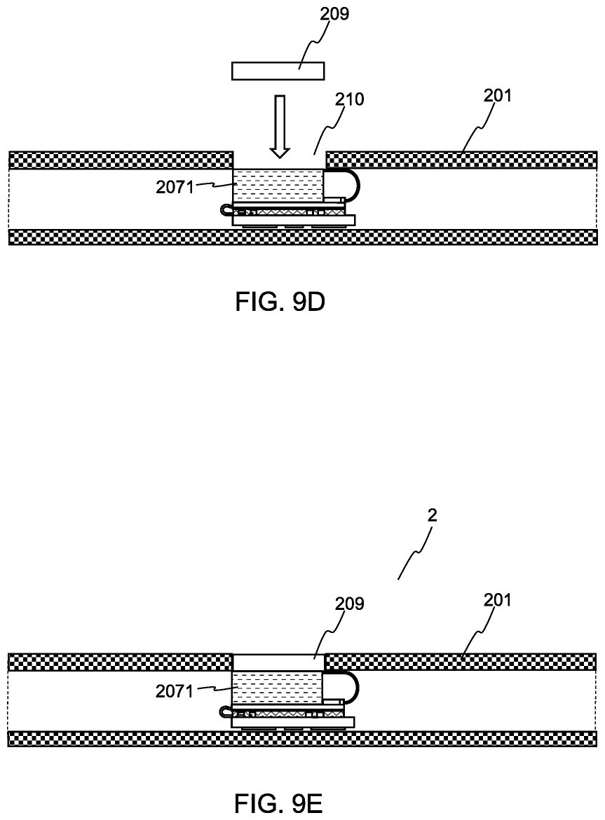

FIG. 9A shows a schematic illustration of an elongate cylindrical housing of an aerosol-generating device, with the control board assembly of FIG. 4B preinstalled inside the housing adjacent to an aperture formed in the housing, with a separate light guide assembly and separate touch sensing module outside of the housing.

FIG. 9B shows a schematic illustration of the light guide assembly being inserted through the aperture to overlie the control board assembly.

FIG. 9C shows a schematic illustration of the touch sensing module being inserted through the aperture to overlie an outward-facing surface of the light guide assembly.

FIG. 9D shows a schematic illustration of a display window being installed in the aperture.

FIG. 9E shows a schematic illustration of the aerosol-generating device after installation of the display window in the aperture.

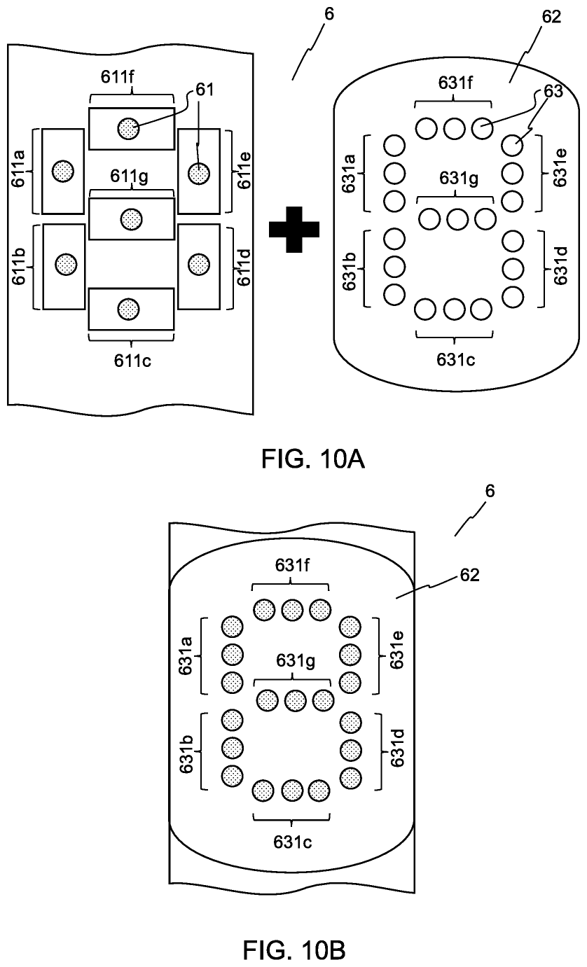

FIGS. 10A and 10B show a schematic plan illustration of a first embodiment of a lighting system prior to and after assembly respectively.

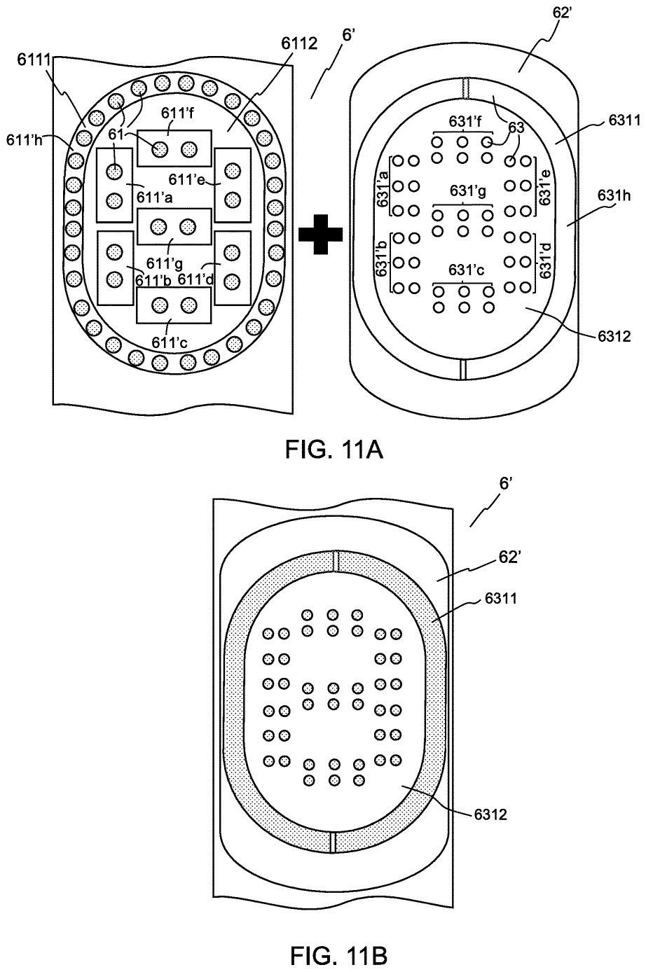

FIGS. 11A and 11B show a schematic plan illustration of a second embodiment of a lighting system prior to and after assembly respectively.

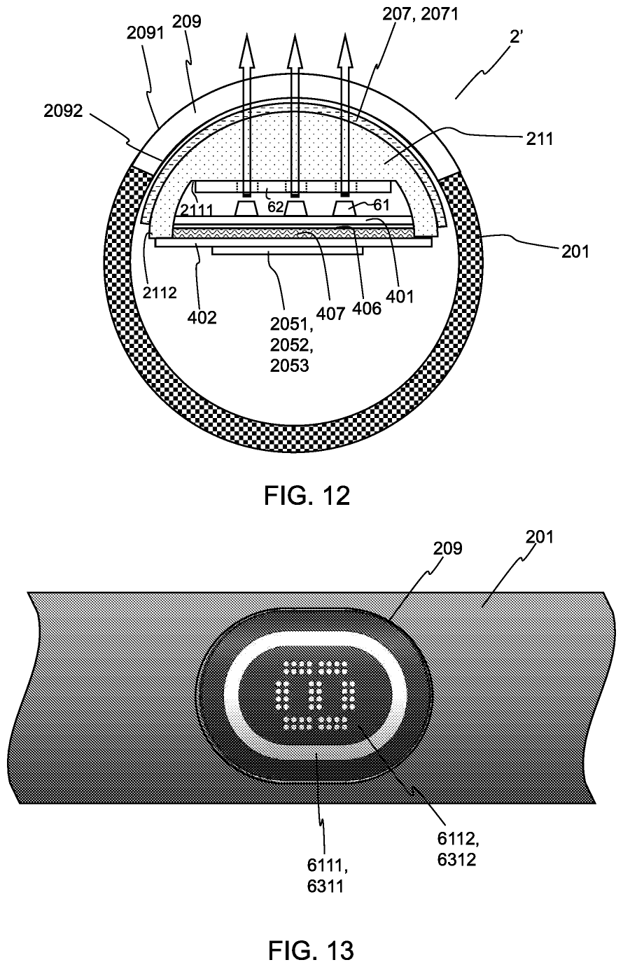

FIG. 12 shows a schematic cross-sectional illustration of an embodiment of an aerosol-generating device incorporating the lighting system of FIG. 10.

FIG. 13 shows a plan view of a display window of an aerosol-generating device, in which the display window overlies the lighting system of FIG. 11.

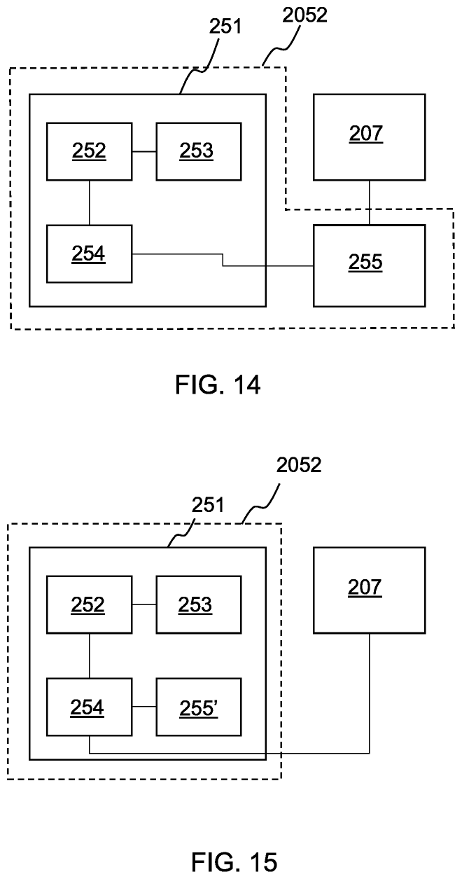

FIG. 14 shows a schematic representation of an embodiment of touch-sensing control electronics for controlling operation of a capacitive touch sensor of the aerosol-generating device illustrated in the above figures.

FIG. 15 shows a schematic representation of an alternative embodiment of touch-sensing control electronics for controlling operation of a capacitive touch sensor of the aerosol-generating device illustrated in the above figures.

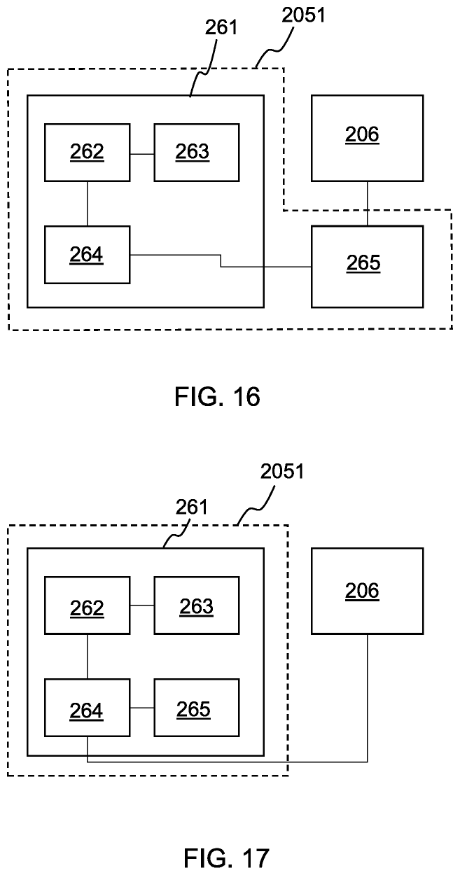

FIG. 16 shows a schematic representation of an embodiment of lighting control electronics for controlling operation of a lighting assembly of the aerosol-generating device illustrated in the above figures.

FIG. 17 shows a schematic representation of an alternative embodiment of lighting control electronics for controlling operation of a lighting assembly of the aerosol-generating device illustrated in the above figures.

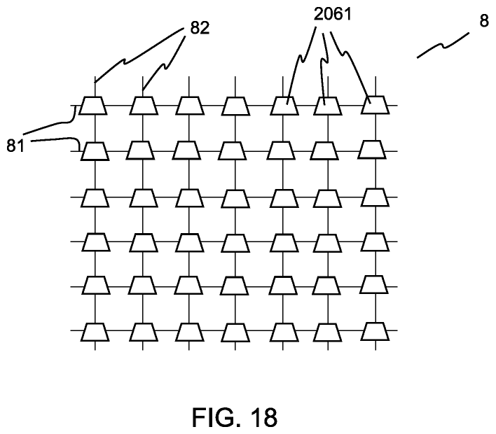

FIG. 18 shows a schematic representation of an arrangement of intersecting row & column pins and accompanying LEDs, for use as part of a lighting assembly of the aerosol-generating device illustrated in the above figures.

FIG. 1 shows the components of an aerosol-generating system 1. The aerosol-generating system 1 has an aerosol-generating device 2 and an aerosol-generating article 3. As will be described below, the aerosol-generating device 2 is adapted to receive the aerosol-generating article 3.

The aerosol-generating article 3 has a wrapper 301 enclosing a rod of aerosol-forming substrate 302 and a mouthpiece element 303. The wrapper 301 may be a cigarette paper or similar. The rod of aerosol-forming substrate 302 is positioned at a distal end 304 of the article 3 and the mouthpiece element 303 positioned at a mouth end 305 of the article. The mouthpiece element 303 may be a filter element formed of cellulose acetate or other suitable material. A susceptor element 306 of ferromagnetic material is positioned inside the rod of aerosol-forming substrate 302.

The aerosol-generating device 2 has an elongate tubular housing 201 extending along a longitudinal axis LA₂. The elongate housing 201 may be formed of a polymer material or other material possessing suitable stiffness. The housing 201 is sized so as to be suitable for being handheld by a user. A blind cavity 202 is defined at a first end 203 of the housing 201. In the embodiment shown in FIG. 1, the housing 201 is cylindrical in cross-section. The cavity 202 is sized to receive the distal end 304 of the aerosol-generating article 3 such that the cavity receives all of the length of the rod of aerosol-forming substrate 302. A power source 204, control electronics 205, lighting assembly 206 and touch sensor 207 are contained inside the interior of the housing 201. In the illustrated embodiment, the power source 204 is a rechargeable battery; for example, the battery may be a lithium-ion battery. An electric heating arrangement is also provided inside the housing. More specifically, in the illustrated embodiment of FIG. 1 the electric heating arrangement is in the form of an inductor coil 208 surrounding the cavity 202. In other embodiments (not shown), the electric heating arrangement may be a resistive heating element; for example, the resistive heating element may have a blade extending from a base of the cavity 202 towards the first end 203 of the housing 201.

The control electronics 205 includes a lighting control electronics section 2051, a touch-sensing control electronics section 2052 and a heating control electronics section 2053. Although not shown in FIG. 1, the control electronics 205 may also include sections relating to the control of other functions of the aerosol-generating device 2. Each of the lighting, touch-sensing and heating control electronics sections 2051, 2052, 2053 may include a controller and a memory module, the memory module containing instructions accessible by the respective controller to enable the respective control electronics section to perform one or more control functions. In the case of the embodiment of the aerosol-generating device 2 shown in FIG. 1, the heating control electronics section 2053 also includes a DC/AC converter (not shown) to convert DC current provided by the battery 204 to an alternating current. As shown schematically in FIG. 1, the lighting control electronics section 2051 is coupled to the lighting assembly 206, the touch-sensing control electronics section 2052 is coupled to the touch sensor 207, and the heating control electronics section 2053 is coupled to the inductor coil 208. Although not shown in FIG. 1, each of the control electronics sections (lighting, touch-sensing and heating) are also communicably coupled to each other so that an input/output to or from one of the control electronics sections may result in a corresponding control input to and/or control output from another of the control electronics sections.

A display window 209 is defined in the housing 201 of the device 2. The outline of the display window 209 is shown in broken outline in FIG. 1. The display window 209 is a transparent plastic insert installed in an aperture 210 defined in the housing 201 of the device 2 (see FIGS. 1 and 2). However, the display window 209 may be formed from other light transmissive materials, such as glass. As will be described in more detail below, the display window 209 serves as both a touch interface for a user to provide control inputs to the device 2 and a window through which one or more light emissions from the lighting assembly 206 may be viewed. The light emissions may be informative of various states of the aerosol-generating device 2. FIG. 2 illustrates an outward-facing surface 2091 of the display window 209 serving as a touch interface for a user.

Prior to activation of the aerosol-generating device 2, the aerosol-generating article 3 is inserted into the cavity 202 of the device. When the article 3 has been fully inserted into the cavity 202, the length of the rod of aerosol-forming substrate 302 is surrounded by the inductor coil 208. On activation of the device 2, the heating control electronics section 2053 controls the supply of alternating electric current from the battery 204 to the inductor coil 208 in accordance with instructions contained in a memory module (not shown) of the heating control electronics section. Activation of the aerosol-generating device 2 may occur automatically on insertion of the aerosol-generating article 3 into the cavity 202 of the device (for example, a sensor may be arranged within the cavity, the sensor configured to detect insertion of the aerosol-generating article). Alternatively, the aerosol-generating device 2 may be activated by a user engaging their finger with the touch interface defined by the outward-facing surface 2091 of the display window 209, with the touch-sensing control electronics section 2052 sensing the touch event and communicating with the heating control electronics section 2053 to commence supply of current from the battery 204 to the inductor coil 208 in order to heat the aerosol-forming substrate 302 of the aerosol-generating article 3. The touch-sensing control electronics section 2052 may also communicate with the lighting control electronics section 2051 to result in the lighting assembly 206 generating a light emission informing the user of the activation of the device 2 and/or a current operational state of the device.

For the aerosol-generating device 2 illustrated in FIG. 1, alternating current through the inductor coil 208 generates a magnetic field. The susceptor element 306 lies within this magnetic field. The magnetic field induces heating of the susceptor element 306 through one or both of eddy currents and magnetic hysteresis. The heating control electronics section 2053 controls the supply of current to the inductor coil 208 in accordance with a heating profile stored in a memory module of the heating control electronics section. The lighting assembly 206 may generate one or more light emissions in response to one or more control inputs by the user, and/or in response to and informative of a given state of the aerosol-generating device 2.

FIGS. 3A to 3D show a first embodiment of a control board assembly 4 for use in the aerosol-generating device 2. The control board assembly 4 contains the control electronics 205 schematically illustrated in FIG. 1. The control board assembly 4 has a first elongate control board 401, a second elongate control board 402, with a hinge element 403 coupling the first and second controls boards to each other. The first control board 401 has a length L₄₀₁ of 20 millimetres, a width W₄₀₁ of 7 millimetres and a thickness t₄₀₁ of 0.7 millimetres. The second control board 402 has a length L₄₀₂ of 25 millimetres, a width W₄₀₂ of 10 millimetres and a thickness t₄₀₂ of 1 millimetre. In the unfolded state of FIG. 3A, the hinge element 403 separates the longitudinal ends of the first and second control boards by a distance L₄₀₃ of 5 millimetres. In other embodiments, the first and second control boards 401, 402 may have a length dimension (L₄₀₁, L₄₀₂) in a range of 10 millimetres to 60 millimetres, or 15 millimetres to 45 millimetres, or 15 millimetres to 30 millimetres. In other embodiments, the first and second control boards 401, 402 may have a width dimension (W₄₀₁, W₄₀₂) in a range of 5 millimetres to 35 millimetres, or 5 millimetres to 25 millimetres, or 5 millimetres to 15 millimetres. In other embodiments, the first and second control boards 401, 402 may have a thickness dimension (t₄₀₁, t₄₀₂) in a range of 0.2 millimetres to 5 millimetres, or 0.2 millimetres to 3 millimetres, or 0.5 millimetres to 2 millimetres. The first control board 401 is formed from a first material composition. The second control board 402 is formed from a second material composition. The first material composition may be a polymer material, whereas the second material composition may be a ceramic material; however, it will be appreciated that other materials may be employed for the first and second material compositions. The first material composition has a lower stiffness than that of the second material composition. For the illustrated embodiment of FIGS. 3A to 3D, the hinge element 403 is an elongate integral extension of the first control board 401 (being formed from the first material composition), extending from one of the longitudinal ends of the first control board and coupled to the second control board 402. The coupling of the hinge element 403 to the second control board 402 may be achieved by use of adhesive between corresponding surfaces of the hinge element and the second control board to define an adhesive interface therebetween. Dependent on the choice of adhesive used, the adhesive interface may be peelable to allow uncoupling of the first and second control boards 401, 402 from each other. The coupling of the hinge element 403 to the second control board 402 may also be achieved by use of a push-fit connection interface. For the illustrated embodiment, the lighting control electronics section 2051, the touch-sensing control electronics section 2052 and the heating control electronics section 2053 are each mounted to a surface 4021 of the second control board 402. A lighting assembly 206 formed of a plurality of LEDs 2061 is arranged on a surface 4011 of the first control board 401. The lighting assembly 206 is coupled to the lighting control electronics 2051 section by means of one or more electrically conductive tracks (not shown) extending between the first and second control boards 401, 402, the tracks embedded in or overlaid on a surface of the hinge element 403. A zero interface force (“ZIF”) connector 404 or similar is also provided on surface 4011 of the first control board 401. The ZIF connector 404 is provided to allow for electromechanical connection between the control board assembly 4 and a touch sensor 207 (such as the touch sensor 207 schematically shown in FIG. 1). The ZIF connector 404 is coupled to the touch-sensing control electronics section 2052 by means of one or more electrically conductive tracks (not shown) extending between the first and second control boards 401, 402, the tracks embedded in or overlaid on a surface of the hinge element 403.

The control board assembly 4 has an initial unfolded state-as shown in FIGS. 3A and 3B—in which the first and second control boards 401, 402 are arranged in end to end relationship with each other, with the hinge element 403 coupling opposed longitudinal ends of the two control boards to each other. To facilitate insertion of the control board assembly 4 inside the interior of the housing 201 of the aerosol-generating device 2, the first control board 401 is folded about a fold axis 405 aligned generally perpendicular to the common longitudinal axis LA₄ of the first and second control boards so as to overlie the second control board 402. The direction of folding about the fold axis 405 is represented by arrows in FIGS. 3A and 3B. FIGS. 3C and 3D show the control board assembly 4 in the folded state. In the folded state, opposed inward-facing surfaces 4012, 4022 of the first and second control boards 401, 402 are spatially separated from each other.

FIGS. 4A and 4B show a second embodiment of a control board assembly 4′ for use in the aerosol-generating device 2, in unfolded and folded states respectively. This second embodiment includes all of the elements of the first embodiment of FIGS. 3A to 3D. However, in this second embodiment a stiffening member 406 and a separator element 407 are also provided. The stiffening member 406 is in the form of a plate formed of a material having a stiffness greater than the first material composition of the first control board 401. The stiffening member 406 may be formed from metal, plastic or any suitable material having a greater stiffness than the first material composition. The stiffening member 406 has a thickness t₄₀₆ of 0.2 millimetres. In other embodiments, the stiffening member 406 may be different in thickness. Further, the thickness chosen for the stiffening member 406 may be influenced by the choice of material used for the stiffening member and the stiffness of that material. In the unfolded state, the flexible first control board 401 is overlaid on to a support surface 4061 of the stiffening member 406. The stiffening member 406 and its support surface 4061 are generally planar. The separator element 407 is formed from a material having a stiffness greater than the first material composition of the first control board 401. In the embodiment illustrated in FIGS. 4A and 4B, the separator element 407 is formed of sheet metal; however, in other embodiments, alternative materials may be used for the separator element 407. A major portion 4071 of the separator element 407 is generally planar, with a pair of laterally opposed longitudinally extending edges 4072 of the separator element bent perpendicular to the major portion. In the unfolded state, the separator element 407 is positioned so that feet 4073 defined on each of the two laterally opposed longitudinally extending edges 4072 locate against surface portions of the second control board 402. To reduce the likelihood of the sheet metal of the separator element 407 resulting in a short circuit between electrical components of the first and second control boards 401, 402, the surface portions of the second control board against which the feet 4073 of the separator element 407 locate are electrically isolated from electrical circuitry of the second control board. With the stiffening member 406 and separator element 407 located against surfaces 4012, 4022 of the first control board 401 and the second control board 402 respectively, the first control board is folded about a fold axis 405′ aligned generally perpendicular to the common longitudinal axis of the first and second control boards so as to overlie the second control board. The direction of folding is represented by an arrow in FIG. 4A, with the fold axis 405′ extending into the page. FIG. 4B shows the control board assembly 4′ in the folded state. The separator element 407 helps to maintain separation between the opposed inward-facing surfaces 4012, 4022 of the first and second control boards 401, 402 in the folded state.

FIGS. 5A to 5C show a third embodiment of a control board assembly 4″ for use in the aerosol-generating device 2. This second embodiment includes all of the elements of the first embodiment of FIGS. 3A to 3D. However, in the initial unfolded state, the first control board 401 and the second control board 402 are laterally spaced apart from each other rather than being in end to end relationship. As shown in FIG. 5A, the longitudinal axes LA₄₀₁, LA₄₀₂ of the first and second control boards 401, 402 are parallel and spaced apart from each other, with the hinge element 403 extending laterally between opposed longitudinally extending edges of the first and second control boards. To facilitate insertion of the control board assembly 4″ inside the interior of the housing 201 of the aerosol-generating device 2, the first control board 401 is folded about a fold axis 405″ aligned generally parallel to the longitudinal axes LA₄₀₁, LA₄₀₂ of the first and second control boards to as to overlie the second control board 402. The direction of folding about the fold axis 405″ is represented by an arrow in FIG. 5A. FIGS. 5B and 5C each show the control board assembly 4″ in the folded state, with FIG. 5B showing a side elevation view in the direction of B-B of FIG. 5A and FIG. 5C showing a side elevation view in the direction of C-C of FIG. 5A. Again, in the folded state, the opposed inward-facing surfaces 4012, 4022 of the first and second control boards 401, 402 are spatially separated from each other. It will be appreciated that one or both of the stiffening member 406 and the separator element 407 of the embodiment of FIGS. 4A and 4B may also be used in the embodiment of FIGS. 5A to 5C.

FIGS. 6A to 6H are provided to help illustrate a first exemplary method of assembly of the aerosol-generating device 2.

FIG. 6A shows the control board assembly 4′ of FIG. 4B. The control board assembly 4′ can be said to form a control module. Also shown in FIG. 6A is a light guide assembly 211 and touch sensor 207. In the state shown in FIG. 6A, the light guide assembly 211 and touch sensor 207 are uncoupled from each other and from the control board assembly 4. The light guide assembly 211 is configured for directing light between opposed inward and outward-facing surfaces 2111, 2112 of the light guide assembly and may have a plurality of channels extending between the inward and outward-facing surfaces. The outward-facing surface 2112 of the light guide assembly 211 is generally convex in profile. In use, light is directed between the inward and outward-facing surfaces 2111, 2112 of the light guide assembly 211 to emerge at two distinct regions on the outward-facing surface. These two distinct regions are an annular outer region 2113 and a central inner region 2114. The outer region 2113 surrounds the inner region 2114. For the light guide assembly 211 shown in FIG. 6A, the outer region 2113 is generally continuous whereas the inner region 2114 consists of a plurality of discrete apertures.

In one example, the touch sensor 207 has an electrically conductive foil mesh 2071 and a ZIF connector 2072. The ZIF connector 2072 is coupled to the foil mesh 2071 by a cable 2073. The foil mesh 2071 is formed of a mesh of copper wires spaced apart from each other, as shown in FIG. 7A, with each wire of the mesh defining an electrode of the foil mesh. However, it will be appreciated that the foil mesh 2071 may be formed from electrically conductive materials other than copper, and that other types of touch sensor could be used (such as those described herein). In another example, the touch sensor 207 comprises one or more electrically conductive regions. The one or more electrically conductive regions may be arranged on an electrically insulating layer, or film. Each one of the electrically conductive regions may have a single or a plurality of electrical connections with an integrated circuit (such as a microcontroller) of the touch-sensing control electronics section 2052 for sensing one or more touch inputs.

FIGS. 7B-E illustrate examples of touch sensors 207, each comprising one or more electrically conductive regions 704 arranged on an electrically insulating layer 702. Each electrically conductive region 704 is connected to the touch-sensing control electronics section 2052 for sensing one or more touch inputs. FIG. 7F illustrates the principle of operation that enables the touch-sensing control electronics section 2052 to detect touch events.

In the touch sensor 207 shown in FIG. 7B, there is a single electrically conductive region 704 arranged on an insulating layer 702. The electrically conductive region 704 is connected to the touch-sensing control electronics section 2052, which is described with reference to FIG. 7F. The electrically conductive region 704 is shielded from direct electrical contact with objects outside of the aerosol-generating device 2 via the display window 209.

Referring to FIG. 7F, the touch-sensing control electronics section 2052 comprises a first switch 708 and a second switch 710. The electrically conductive region 704 is electrically connected between the first switch 708 and the second switch 710. The electrically conductive region 704 may have a capacitance. The capacitance of the electrically conductive region 704 may be up to 100 pF, between 5 pF and 50 pF, between 10 pF and 30 pF, or between 15 pF and 25 pF.

The touch-sensing control electronics section 2052 controls the first and second switches 708, 710 by opening the second switch 710 and closing the first switch 708 for a first time duration (T1). During T1, an electrical charge forms due to the capacitance of the electrically conductive region 704.

Then, the touch-sensing control electronics section 2052 opens the first switch 708 and closes the second switch 710 for a second time duration (T2). During T2, the charge accumulated at the electrically conductive region 704 is transferred to a sensing capacitor 706.

The touch-sensing control electronics section 2052 determines the time taken (Tx) for the sensing capacitor 706 to reach a voltage threshold (Vth). The determined value for Tx is indicative of a touch event. For example, Tx will be equal to a value within a certain range or above a threshold when there is no touch event; for example, when a user is not touching the display window 209. However, if there is a touch event (for example, when a user presses the display window 209 with a finger), there will be a larger capacitance at the electrically conductive region 704 and Vth will be reached more quickly. In other words, when there is a touch event, Tx will be shorter. Thus, the touch-sensing control electronics section 2052 determines that a touch event has occurred by determining that Tx is within a range associated with a touch event, or that Tx has breached a threshold associated with a touch event.

In the touch sensor 207′ shown in FIG. 7C, there are three electrically conductive regions 704′a, 704′b, 704′c on an electrically insulating layer 702. Each one of the electrically conductive regions 704′a, 704′b, 704′c is connected to the touch-sensing control electronics section 2052 which detects touch events as described with reference to FIG. 7F.

Since there is a plurality of electrically conductive regions, the touch-sensing control electronics section 2052 can determine a region of the display window 209 that has been touched. If a touch event is detected at electrically conductive region 704′a, the touch-sensing control electronics section 2052 determines that the top of the window 209 has been touched. If a touch event is detected at electrically conductive region 704′b, the touch-sensing control electronics section 2052 determines that the middle of the window 209 has been touched. If a touch event is detected at electrically conductive region 704′c, the touch-sensing control electronics section 2052 determines that the bottom of the window 209 has been touched.

Since the touch sensor 207′ has electrically conductive regions 704′a, b, c distributed along an axis y, the touch-sensing control electronics section 2052 can determine a direction of movement of a user's finger along the axis y. For instance, if a touch event is detected at electrically conductive region 704′a, then 704′b, and then 704′c, the touch-sensing control electronics section 2052 determines that the user has swiped down along the y axis.

Alternatively, if a touch event is detected at electrically conductive region 704′c, then 704′b , and then 704′a, the touch-sensing control electronics section 2052 determines that the user has swiped up along the y axis. The touch-sensing control electronics may be configured to perform a function associated with a touch event at a particular electrically conductive region and/or to perform a function associated with a particular direction of movement (or gesture) performed by a user's finger.

In the touch sensor 207″ shown in FIG. 7D, there are six electrically conductive regions 704″a, 704″b, 704″c, 704″d, 704″e, 704″f on an electrically insulating layer 702.

Each one of the electrically conductive regions 704″a, 704″b, 704″c, 704″d, 704″e, 704″f is connected to the touch-sensing control electronics section 2052 which detects touch events as described with reference to FIG. 7F.

The touch-sensing control electronics section 2052 can determine a region of the display window 209 that has been touched by detecting a touch event at regions 704″a-f corresponding with a region at the window 209. The touch-sensing control electronics section 2052 detects the location of a touch event in a similar manner to as described with reference to FIG. 7C.

Since the touch sensor 207″ has electrically conductive regions 704″a-f distributed across a two-dimensional area, the touch-sensing control electronics can determine a direction of movement of a user's finger along an axis y and a second axis x. For instance, if a touch event is detected at electrically conductive region 704″d, and then 704″c, the touch-sensing control electronics section 2052 determines that the user has swiped right along the x axis. Alternatively, if a touch event is detected at electrically conductive region 704″c, then 704″d, the touch-sensing control electronics section 2052 determines that the user has swiped left along the x axis. Movement along the y axis can be detected in a similar manner to as described with reference to FIG. 7C.

It is also possible to detect movement in a diagonal direction. For instance, the touch-sensing control electronics 2052 can determine a movement of a finger upwards and rightwards by detecting a touch event at region 704″e and then at region 704″c.

The touch-sensing control electronics may be configured to perform a function associated with a touch event at a particular electrically conductive region and/or to perform a function associated with a particular direction of movement (or gesture) performed by a user's finger.

In the touch sensor 207″ shown in FIG. 7E, there are five electrically conductive regions 704′″a, 704′″b, 704″c, 704′″d, 704′″e on an electrically insulating layer 702. Specifically, there is a central region 704′″e surrounded by a plurality of separate regions 704′″a, 704′″b, 704′″c, 704′″d. Each one of the electrically conductive regions 704′″a, 704′″b , 704′″c, 704′″d, 704′″e is connected to the touch-sensing control electronics section 2052 which detects touch events as described with reference to FIG. 7F.

The touch-sensing control electronics section 2052 can determine a region of the display window 209 that has been touched by detecting a touch event at region 704′″a-e corresponding with a region at the window 209. The touch-sensing control electronics section 2052 detects the location of a touch event in a similar manner to as described above.

Since the touch sensor 207′″ has electrically conductive regions 704′″a-e distributed across a two-dimensional area, the touch-sensing control electronics can determine a direction of movement of a user's finger along an axis y and a second axis x as described above.

The touch-sensing control electronics may be configured to perform a function associated with a touch event at a particular electrically conductive region and/or to perform a function associated with a particular direction of movement (or gesture) performed by a user's finger.

As shown in FIG. 6B, subsequent to the state shown in FIG. 6A, the light guide assembly 211 is mounted to the first control board 401 of the control board assembly 4′ so as to overlie the lighting assembly 206.

As shown in FIG. 6C, subsequent to the state shown in FIG. 6B, the foil mesh 2071 of the touch sensor 207 is arranged over and in contact with the convex outward-facing surface 2112 of the light guide assembly 211. The foil mesh 2071 of the touch sensor 207 may be preformed into the convex profile illustrated in FIG. 6A and then simply placed onto the convex outward-facing surface 2112 of the light guide assembly 211. Alternatively, the foil mesh 2071 of the touch sensor 207 may be initially provided in a planar state and subsequently deformed into the convex profile shown in FIG. 6A during the process of overlaying the foil mesh onto the convex outward-facing surface 2112 of the light guide assembly 211. The convex profile of the foil mesh 2071 generally corresponds to the profile of the outward-facing surface 2112 of the light guide assembly 211 so that the foil mesh is in surface contact with the outward-facing surface of the light guide assembly. The ZIF connector 2072 of the touch sensor 207 is coupled to the corresponding ZIF connector 404 on the first control board 401, thereby establishing electrical communication between the foil mesh 2071 and the touch sensing control electronics section 2052 of the control board assembly 4′. The combination of the control board assembly 4′, light guide assembly 211 and touch sensor 207 shown in FIG. 6C forms an intermediate assembly module 5.

FIG. 6D shows a view of a portion of the length of the elongate tubular housing 201. The housing 201 includes the aperture 210 for receiving the display window 209, but for this illustrated embodiment the display window is not yet installed in the aperture. In an alternative embodiment, the display window 209 may be preinstalled in the aperture 210. An opening 212 is defined at a second end 213 of the housing 201. The intermediate assembly module 5 is initially located adjacent to the opening 212 and is then inserted into the housing 201. More specifically, the intermediate assembly module 5 is slid along the length of the housing 201 to a predetermined location. The predetermined location corresponds to the lighting assembly 206 being positioned adjacent to the aperture 210 in the housing 201—as shown in FIG. 6E.

As shown in FIG. 6F, subsequent to the state shown in FIG. 6E, the display window 209 is installed in the aperture 210 of the housing 201 to overlie the foil mesh 2071 of the touch sensor 207. FIG. 6G shows the assembled aerosol-generating device 2 after installation of the display window 209 in the aperture 210.

FIG. 6H shows a cross-section through section D-D of FIG. 6G. The display window 209 has a uniform thickness. The display window 209 also has a curvature corresponding to the curvature of the foil mesh 2071 and the outward-facing surface 2112 of the light guide assembly 211. The curvature of the display window 209 also corresponds to the curvature of the sidewall of the cylindrical elongate housing 201. The distance between a point on the outward-facing surface of the foil mesh 2071 and the outward-facing surface 2091 of the display window 209, when measured along a line normal to a point on the mesh surface, is generally uniform along the entirety of the region where the display window overlies the foil mesh. In the embodiment shown in FIG. 6H, a small air gap exists between the outward-facing surface of the foil mesh 2071 and the inward-facing surface 2092 of the display window 209. However, in other embodiments, the foil mesh 2071 may be in intimate contact with the inward-facing surface 2092 of the display window 209 such that the foil mesh is effectively sandwiched between the outward-facing surface 2112 of the light guide assembly 211 and the inward-facing surface 2092 of the display window 209.

In use, light emitted by the LEDs 2061 of the lighting assembly 206 passes through channels defined between the inward and outward-facing surfaces 2111, 2112 of the light guide assembly 211, and then through the foil mesh 2071 of the touch sensor 207, to be transmitted through the display window 209. Contact between a user's finger and a location on the outward-facing surface 2091 of the display window 209 results in a change in capacitive coupling between adjacent wires of the foil mesh 2071 at the location on the mesh immediately underlying the touch location. More specifically, contact of the user's finger with the display window 209 has the effect of reducing capacitive coupling between adjacent wires of the foil mesh 2071 underlying the contact location; this corresponds to a mutual capacitance mode of operation of the touch sensor 207. This change in capacitive coupling is detected by the touch-sensing control electronics section 2052. The nature of the touch input may be determined by the touch-sensing control electronics section 2052; for example, the touch sensing control electronics may identify whether the user's finger slides over the outward-facing surface 2091 of the display window 209 or engages with the surface 2091 at a single point. The touch-sensing control electronics section 2052 may generate an output signal in response to and dependent on the nature of the touch input. This output signal may be communicated to one or both of the lighting control electronics section 2051 and the heating control electronics section 2053. Where the output signal is conveyed to the lighting control electronics section 2051, the lighting control electronics section may generate a light emission 2062 from the light emitting elements 2061. The nature of the light emission 2062 (for example, colour, luminance, duration or periodicity of the light emission) may be dependent on the nature of the touch input. Where the output signal is conveyed to the heating control electronics section 2053, the heating control electronics section may act to initiate or pause the flow of current to the inductor coil 208 of the aerosol-generating device 2.

FIG. 8 illustrates an embodiment in which the touch sensor 207 is coupled to the control board assembly 4 of FIG. 3D, but without the presence of a light guide assembly 211. For the embodiment of FIG. 8, the foil mesh 2071 of the touch sensor 207 is preformed into a convex profile prior to the ZIF connector 2072 of the touch sensor being connected to ZIF connector 404 of the first control board 401. The curvature of the convex profile of the foil mesh 2071 generally corresponds to the curvature of the inward-facing surface 2092 of the display window 209 and/or the inner surface of the cylindrical elongate housing 201 of the aerosol-generating device 2.

FIGS. 9A to 9E are provided to help illustrate a second exemplary method of assembly of the aerosol-generating device 2.

FIG. 9A shows the control board assembly 4 of FIGS. 3C and 3D preinstalled inside the elongate tubular housing 201 at a position adjacent to and under the aperture 210 defined in the housing. The display window 209 has not yet been installed in the aperture 210. Also shown in FIG. 9A is the light guide assembly 211 and touch sensor 207. In the state shown in FIG. 9A, the light guide assembly 211 and touch sensor 207 are uncoupled from each other and from the control board assembly 4.

As shown in FIG. 9B, the light guide assembly 211 is inserted into or dropped through the aperture 210 so as to overlie the lighting assembly 206. FIG. 9C shows the light guide assembly 211 after insertion and positioning over the lighting assembly 206.

FIG. 9C also shows that after insertion and positioning of the light guide assembly 211, the touch sensor 207 is then inserted into or dropped through the aperture 210 so that the foil mesh 2071 of the touch sensor 207 is arranged over and in contact with the convex outward-facing surface 2112 of the light guide assembly 211. The cable 2073 is of sufficient length such that, prior to insertion of the foil mesh 2071 through the aperture 210, the ZIF connector 2072 of the touch sensor 207 is able to be connected to the ZIF connector 404 of the first control board 401. FIG. 9D shows the touch sensor 207 after insertion and positioning over the light guide assembly 211. In other embodiments, the light guide assembly 211 and touch sensor 207 may be pre-assembled outside of the housing 201 to form a combined assembly module, with the combined assembly module inserted into or dropped through the aperture 210 to couple with the control board assembly 4.

FIG. 9D also shows the installation of the display window 209 in the aperture 210, with FIG. 9E showing the assembled aerosol-generating device 2 after installation of the display window 209 in the aperture 210.

As can be understood from comparison of FIGS. 9E and 6G, the first and second methods of assembly (“slide-inside” and “drop-in” respectively) are able to result in the same configuration of the aerosol-generating device.

FIG. 10A shows a first embodiment of a lighting system 6 prior to assembly. The lighting assembly has a plurality of LEDs 61 and an opaque shield 62. The plurality of LEDs 61 are grouped in a plurality of lighting areas 611. For the embodiment of FIG. 10A, there are seven lighting areas 611a-g, each lighting area having a single one of the LEDs 61. In other examples, there may be a plurality of LEDs 61 per lighting area 611; for example, there may be 2, 3, 4 or more LEDs 61 per lighting area. The opaque shield 62 is formed of plastic; however, it will be appreciated that other materials may be used which are non-transmissive to the passage of light. The opaque shield 62 is formed with a plurality of apertures 63. The plurality of apertures 63 are grouped in a plurality of aperture areas 631. For the embodiment of FIG. 10A, there are seven aperture areas 631a-g. The apertures 63 of each aperture area 631a-g are arranged in co-linear relationship with each other, with each aperture area having a line of three apertures in this example. In another example, each aperture area may have a plurality of lines of apertures (for example, 2, 3, 4 or more lines), each line of apertures comprising 2, 3, 4, or more apertures. The aperture areas are positioned relative to each other so as to define the shape of the number ‘8’.

FIG. 10B shows the lighting system 6 in an assembled state, in which the opaque shield 62 is positioned over the plurality of LEDs 61. The aperture areas 631a-g are arranged across the area of the opaque shield 62 such that in the assembled state, each one of the aperture areas 631a-g overlies a corresponding single one of the lighting areas 611a-g. So, in use of the lighting system 6, light from the single LED 61 of lighting area 611a is visible through the three apertures 63 of aperture area 631a; the same correspondence applies to each of the remaining lighting areas 611b-g and aperture areas 631b-g. The LEDs 61 of the plurality of lighting areas 611a-g are designed to be driven by control electronics (for example, the lighting control electronics section 2051 described above). By selectively activating different ones of the lighting areas 611a-g alone or in combination with each other, the lighting system 6 is able to generate light emissions defining the form of different numbers, letters or shapes.

FIG. 11A shows a second embodiment of a lighting system 6′ prior to assembly. The lighting assembly 6′ has a plurality of LEDs 61 and an opaque shield 62′. The plurality of LEDs 61 are grouped in a plurality of lighting areas 611′a-h. The lighting area 611′h of LEDs 61 forms a first set 6111 of the plurality of lighting areas and is generally in the shape of an oval ring. The lighting areas 611a-g of LEDs 61 form a second set 6112 of the plurality of lighting areas and is generally in the form of an oval. As can be seen from FIG. 11A, the first set 6111 surrounds the second set 6112. Each of lighting areas 611′a-g has two LEDs 61. The plurality of apertures 63 of the opaque shield 62′ are grouped in a plurality of aperture areas 631′. For the embodiment of FIG. 11A, there are eight aperture areas 631′a-h. The aperture area 631 h forms a first set 6311 of the plurality of aperture areas and is generally in the shape of an oval ring. The aperture areas 631′a-g form a second set 6312 of the plurality of aperture areas. The apertures 63 of aperture areas 631′a-g are arranged in two parallel lines of three apertures 63. The second set 6312 of aperture areas are positioned relative to each other so as to define the shape of the number ‘8’.

FIG. 11B shows the lighting system 6′ in an assembled state, in which the opaque shield 62′ is positioned over the plurality of LEDs 61. The aperture areas 631′a-h are arranged across the area of the opaque shield 62′ such that in the assembled state, each one of the aperture areas 631′a-h overlies a corresponding single one of the lighting areas 611′a-h. So, in use of the lighting system 6′, light from the two LEDs of lighting area 611′a is visible through the six apertures 63 of aperture area 631′a; the same correspondence applies to each of the remaining lighting areas 611′b-h and aperture areas 631′b-h. The LEDs of the plurality of the lighting areas 611′a-h are designed to be driven by control electronics (for example, the lighting control electronics section 2051 described above). The LEDs 61 forming the first set 6111 of the plurality of lighting areas may be controlled to all be activated simultaneously, thereby illuminating to define the shape of an oval ring. Alternatively, the control electronics may instead activate only a subset of the LEDs 61 of the first set 6111. By selectively activating different ones of the lighting areas 611′b-g, which make up the second set 6112, alone or in combination with each other, the lighting system 6′ is able to generate a light emission defining the form of different numbers, letters or shapes. Where the lighting system 6′ is installed in an aerosol-generating device (such as device 2 discussed above), the control electronics may be configured to selectively activate one of the first and second sets 6111, 6112 of lighting areas 611′a-h to generate a first light emission corresponding to a first state of the device 2, and to selectively activate the other of the first and second sets of lighting areas to generate a second light emission corresponding to a second state of the device. The first and second light emissions may be different to each other; for example, in one or more of colour, luminance, duration, periodicity. The first and second states may correspond to any given state of the device 2. By way of example, the first and second states may include: a) the power source 204 of the aerosol-generating device 2 containing sufficient energy to complete a single usage session; b) the power source 204 containing sufficient energy to complete two, three or more usage sessions; c) the power source 204 containing a level of energy below a predetermined threshold level of energy; d) selection or activation of one of a first predetermined thermal profile and a second predetermined thermal profile, in which each of the first and second predetermined thermal profiles define a heating profile for heating of the aerosol-forming substrate 302 by an electrical heating arrangement (for example, inductor coil 208) over a usage session, the first and second predetermined thermal profiles being different to each other; e) the aerosol-generating device 2 being in one of a pause mode state or a reactivation state; f) selection or activation of a change in operational state of the aerosol-generating device 2; g) progression through a usage session; h) progression through a pre-heating phase in which an electrical heating arrangement (for example, inductor coil 208) is heated to a predetermined target temperature; i) the aerosol-generating device being in a locked state in which the device is prohibited from generating aerosol; j) the aerosol-generating device being in an unlocked state in which the device is permitted to generate aerosol; k) a PIN number for unlocking the device such that it is permitted to generate aerosol; I) a type of a plurality of aerosol-generating articles being detected by the device; m) the aerosol-generating device being too hot to permit aerosol-generation; and n) the aerosol-generating device being too cold to permit aerosol-generation.

FIG. 12 shows a schematic cross-sectional illustration of an embodiment of the aerosol-generating device 2′ incorporating the lighting system 6 of FIG. 10. The embodiment of FIG. 12 includes all of the features of the aerosol-generating device shown in FIG. 6H. As can be seen in FIG. 12, the LEDs 61 of the lighting system 6 are arranged on surface 4011 of the first control board 401. The opaque shield 62 of the lighting system 6 is arranged between the LEDs 61 and light guide assembly 211. In an alternative embodiment, the opaque shield 62 may instead be overlaid on the outward-facing surface 2112 of the light guide assembly 211. In a further alternative embodiment, the opaque shield 62 may be incorporated into the structure of the display window 209.

FIG. 13 shows a plan view of a display window 209 of an aerosol-generating device 2, in which the display window overlies the lighting system 6′ of FIG. 11. FIG. 13 represents a state in which all of the LEDs 61 are activated, resulting in the first set 6111 (i.e. lighting area 611′h) illuminating through the first set 6311 of aperture area 631′h to define the shape of an illuminated oval, and the second set 6112 of lighting areas 611′a-g illuminating through the second set 6312 of aperture areas 631′a-g to define the shape of an illuminated figure ‘8’. It will be appreciated that the presence of the foil mesh 2071 of touch sensor 207 under the display window 209 also permits the outward-facing surface of the display window to also serve as a touch interface for a user's finger(s).

FIG. 14 is a schematic representation of an exemplary embodiment of the touch-sensing control electronics section 2052 for controlling operation of the capacitive touch sensor 207 of the aerosol-generating device 2 illustrated in the above figures. The touch sensing control electronics section 2052 is shown in broken outline in FIG. 14. The touch sensing control electronics section 2052 has a microcontroller 251 containing a processor 252, memory 253 and input-output means 254. The touch sensing control electronics section 2052 also has a touch sensor driver 255. The touch sensor driver 255 is separate to the microcontroller 251 but communicably coupled thereto via the input-output means 254. The touch sensor driver 255 is also communicably coupled to the touch sensor 207. The touch sensor driver 255 detects a touch event based on electrical signals from the touch sensor 207 in response to occurrence of the touch event; the touch event might be a user's finger having contacted the outward-facing surface 2091 of the display window 209. After determining the occurrence of the touch event, the touch sensor driver 255 sends one or more data signals to the microcontroller 251 via the input-output means 254, the data signals being indicative of the occurrence of the touch event. After the microcontroller 251 receives the data signals, the processor 252 accesses instructions contained in the memory 253 and generates one or more control signals for communicating to one or more of the lighting control electronics section 2051, the heating control electronics section 2053 and other control electronics sections of the aerosol-generating device 2. In this manner, the occurrence of a touch event on the display screen 209 is able to result in one or more control inputs to control one or more of the lighting assembly 206 (or the lighting system 6, 6′), the inductor coil 208 and other features of the aerosol-generating device 2.

FIG. 15 is a schematic representation of an alternative exemplary embodiment of the touch-sensing control electronics section 2052 for controlling operation of the capacitive touch sensor 207 of the aerosol-generating device 2. This embodiment differs from the embodiment of FIG. 14 in that the microcontroller 251 contains touch sensing circuitry 255′, rather than using a separate touch sensor driver 255. The touch sensing circuitry 255′ detects a touch event based on electrical signals received from the touch sensor 207 (via the input-output means 254) in response to occurrence of the touch event; again, the touch event might be a user's finger having contacted the outward-facing surface 2091 of the display window 209. After determining the occurrence of the touch event, the touch sensing circuitry 255′ outputs a signal to the processor 252 via the input-output means 254, the signal being indicative of the occurrence of the touch event. The processor 252 then accesses instructions contained in the memory 253 and generates one or more control signals for communicating to one or more of the lighting control electronics section 2051, the heating control electronics section 2053 and other control electronics sections of the aerosol-generating device 2. In this manner, the occurrence of a touch event on the display screen 209 is able to result in one or more control inputs to control one or more of the lighting assembly 206 (or lighting system 6), the inductor coil 208 and other features of the aerosol-generating device 2. Although not shown in FIG. 15, the touch sensing circuitry 255′ may include a sampling capacitor, with the touch sensing circuitry outputting the signal indicative of a touch event by charging a sampling capacitor to a voltage indicative of the touch event.

FIG. 16 is a schematic representation of an exemplary embodiment of the lighting control electronics section 2051 for controlling operation of the lighting assembly 206 of the aerosol-generating device 2 illustrated in the above figures. The lighting control electronics section 2051 is shown in broken outline in FIG. 16. The lighting control electronics section 2051 has a microcontroller 261 containing a processor 262, memory 263 and input-output means 264. The lighting control electronics section 2051 also has an LED driver 265. The LED driver 265 is separate to the microcontroller 261 but communicably coupled thereto via the input-output means 264. The LED driver 265 is also communicably coupled to the LEDS 2061 of the lighting assembly 206 so as to control the LEDs. As previously discussed, the lighting control electronics section 2051 may be communicably coupled to the touch sensing control electronics section 2052, so that the LED driver 265 may control the LEDs 2061 of the lighting assembly 206 in response to a touch event being detected by the touch sensing control electronics section 2052.

FIG. 17 is a schematic representation of an alternative exemplary embodiment of the lighting control electronics section 2051 for controlling operation of the lighting assembly 206 of the aerosol-generating device 2. This embodiment differs from the embodiment of FIG. 16 in that the LED driver 265 is integrated into the microcontroller 261, rather than being separate therefrom. The LED driver 265 controls the LEDs 2061 of the lighting assembly 206 via the input-output means 264. The LED driver 265 may control the LEDs 2061 of the lighting assembly 206 in response to a touch event being detected by the touch sensing control electronics section 2052.

FIG. 18 is a schematic representation illustrating how the LEDs 2061 of the lighting assembly 206 may be coupled to an arrangement 8 of intersecting row pins 81 and column pins 82. As can be seen, a single LED 2061 is coupled to the intersection of each rod pin 81 and column pin 82. When used in combination with the lighting control electronics sections 2051 of FIG. 16 or 17, the LED driver 265 operates to illuminate each one of the plurality of LEDs 2061 by activating the row pin 81 and the column pin 82 to which the respective LED is connected. The LED driver 265 may operate to activate a single one of the LEDs 2061 or any combination of multiple ones of the LEDs.

For the purpose of the present description and of the appended claims, except where otherwise indicated, all numbers expressing amounts, quantities, percentages, and so forth, are to be understood as being modified in all instances by the term “about”. Also, all ranges include the maximum and minimum points disclosed and include any intermediate ranges therein, which may or may not be specifically enumerated herein. In this context, therefore, a number “A” is understood as “A” ±10% of “A”. Within this context, a number “A” may be considered to include numerical values that are within general standard error for the measurement of the property that the number “A” modifies. The number “A”, in some instances as used in the appended claims, may deviate by the percentages enumerated above provided that the amount by which “A” deviates does not materially affect the basic and novel characteristic(s) of the claimed invention. Also, all ranges include the maximum and minimum points disclosed and include any intermediate ranges therein, which may or may not be specifically enumerated herein. The terms “in which” and “wherein” are used synonymously through this specification.

1.-15. (canceled)

16. A control board assembly for an aerosol-generating system, the control board assembly comprising:
a first elongate control board;
a second elongate control board;
a lighting assembly comprising one or more light emitting elements arranged on one or both of the first control board and the second control board;
control electronics distributed over one or both of the first control board and the second control board, at least a portion of the control electronics being configured to control operation of the lighting assembly;
a hinge element coupling the first control board to the second control board;
wherein the control board assembly has an unfolded state and a folded state,
wherein in the folded state one of the first and the second control boards is folded about the hinge element to overlie the other of the first and the second control boards, and
wherein the first control board and the second control board are arranged such that in the folded state opposing inward-facing surfaces of the first control board and the second control board are spatially separated from each other; and
a separator element, wherein in the folded state the separator element is disposed between the opposing inward-facing surfaces of the first control board and the second control board, a major portion of the separator element being generally planar, the separator element comprising a pair of laterally opposed longitudinally extending edges bent perpendicular to the major portion, wherein feet are defined on each of the laterally opposed longitudinally extending edges, the feet being located against surface portions of the second control board.

17. The control board assembly according to claim 16, wherein the lighting assembly is arranged on an outward-facing surface of the first control board, the outward-facing surface being associated with the folded state of the control board assembly.

18. The control board assembly according to claim 16, wherein the first control board is formed from a first material composition and the second control board is formed from a second material composition, the first material composition having a lower stiffness than that of the second material composition.

19. The control board assembly according to claim 18, further comprising a stiffening member having a stiffness greater than the first material composition, the first control board being overlaid on a support surface of the stiffening member.

20. The control board assembly according to claim 16, wherein the hinge element is formed of a material composition having a lower stiffness than a material composition of the second control board.

21. The control board assembly according to claim 16, wherein the hinge element is formed of a resilient and/or bendable material.

22. The control board assembly according to claim 16, wherein the hinge element is configured to provide an electrically conductive pathway between the first control board and the second control board.

23. The control board assembly according to claim 22, wherein the electrically conductive pathway comprises one or more electrically conductive tracks overlaid on or embedded in the hinge element.

24. The control board assembly according to claim 16, wherein the hinge element is an extended integral portion of the first control board.

25. The control board assembly according to claim 24, wherein the extended integral portion is detachably coupled to the second control board.

26. The control board assembly according to claim 16, wherein the hinge element extends between laterally extending edges of the first control board and the second control board.

27. The control board assembly according to claim 16, wherein the first control board is configured for electrical coupling with a capacitive touch sensing module.

28. An aerosol-generating device for generating an inhalable aerosol from an aerosol-forming substrate, the aerosol-generating device comprising:
an elongate housing extending in a longitudinal direction;
a display window defined in the housing; and
the control board assembly according to claim 16, wherein the control board assembly is disposed within the elongate housing such that such that light emitted by the lighting assembly is visible via the display window.

29. A method of assembling an aerosol-generating device, the method comprising steps of:
providing an elongate tubular housing having a sidewall extending in a longitudinal direction, the sidewall comprising an aperture for a display window;
providing a control module, a lighting assembly, and a touch sensing module, the touch sensing module being configured for detecting a touch of a user, the lighting assembly being arranged on a surface of the control module, the control module comprising control electronics configured to control at least one of the lighting assembly and the touch sensing module;
coupling the touch sensing module to the control module such that the touch sensing module overlies the lighting assembly, thereby forming an intermediate assembly module;
positioning the intermediate assembly module adjacent to an opening defined at one end of the elongate tubular housing; and
sliding the intermediate assembly module within the elongate tubular housing along the longitudinal direction to a predetermined location, the predetermined location corresponding to the lighting assembly being positioned adjacent to the aperture.

30. A method of assembling an aerosol-generating device, the method comprising steps of:
providing an elongate tubular housing having a sidewall extending in a longitudinal direction, the sidewall comprising an aperture for a display window, a control module disposed inside the elongate tubular housing and positioned adjacent to the aperture, wherein a lighting assembly is arranged on a surface of the control module;
providing a touch sensing module configured to detect a touch of a user; and
inserting the touch sensing module through the aperture to couple with the control module such that the touch sensing module overlies the lighting assembly,
wherein the control module comprises control electronics configured to control at least one of the lighting assembly and the touch sensing module.
